(19) United States
(12) Patent Application Publication
(10) Pub. No.: US 2025/0212668 A1
(43) Pub. Date: Jun. 26, 2025

(54) ELECTRONIC DEVICE

(71) Applicant: InnoLux Corporation, Miao-Li County (TW)

(72) Inventors: Chandra LIUS, Miao-Li County (TW); Kuan-Feng LEE, Miao-Li County (TW)

(73) Assignee: InnoLux Corporation, Miao-Li County (TW)

(21) Appl. No.: 18/957,851

(22) Filed: Nov. 24, 2024

(30) Foreign Application Priority Data
Dec. 22, 2023 (CN) 202311777090.0

(51) Int. Cl. H10K 59/80; G06V 40/13; H10K 39/34; H10K 59/122

(52) U.S. Cl. CPC H10K 59/8792; H10K 39/34; H10K 59/122; G06V 40/1318

(57) ABSTRACT

The present disclosure provides an electronic device including a circuit substrate, a partition layer, a light receiving layer, a light emitting layer, and a first light blocking pattern. The partition layer is disposed on the circuit substrate and includes a first opening, a second opening, and a partition wall located between the first opening and the second opening. The light receiving layer is disposed in the first opening, and the light emitting layer is disposed in the second opening. The first light blocking pattern is disposed on the partition wall. In a cross-sectional view of the electronic device, the first light blocking pattern has a first width at a first height and a second width at a second height higher than the first height, and the first width is different from the second width.

### BACKGROUND OF THE DISCLOSURE

### 1. Field of the Disclosure

The present disclosure relates to an electronic device and particularly to an electronic device with a light receiving layer and a light emitting layer.

### 2. Description of the Prior Art

With the advancement of the technology, the electronic device with light sensing and displaying function has been developed. However, in the present electronic device, light emitted by the light emitting element has to pass through multiple films or layers before shining on the object to be detected, such that stray light, which does not shined on the object to be detected, may easily be reflected to the light sensor causing the noise ratio of the received light signal being too high, which lowers the signal to noise ratio (SNR). In this way, it may easily cause inaccurate signal judgments, for example, misjudgments of fingerprint images.

### SUMMARY OF THE DISCLOSURE

It is an objective of the present disclosure to provide an electrode device to solve above problems.

According to an embodiment of the present disclosure, an electronic device is provided, which includes a circuit substrate, a partition layer, a light receiving layer, a light emitting layer, and a first light blocking pattern. The partition layer is disposed on the circuit substrate and includes a first opening, a second opening, and a partition wall located between the first opening and the second opening. The light receiving layer is disposed in the first opening, and the light emitting layer is disposed in the second opening. The first light blocking pattern is disposed on the partition wall. In a cross-sectional view of the electronic device, the first light blocking pattern has a first width at a first height and a second width at a second height higher than the first height, and the first width is different from the second width.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates a cross-sectional view of an electronic device according to a first modified embodiment of a first embodiment of the present disclosure.

FIG. 3 schematically illustrates a cross-sectional view of an electronic device according to a second modified embodiment of a first embodiment of the present disclosure.

FIG. 4 schematically illustrates a cross-sectional view of an electronic device according to a third modified embodiment of a first embodiment of the present disclosure.

FIG. 5 schematically illustrates a cross-sectional view of an electronic device according to a second embodiment of the present disclosure.

FIG. 6 schematically illustrates a top view of an electronic device according to some embodiments of the present disclosure.

FIG. 7 schematically illustrates a cross-sectional view of an electronic device according to a first modified embodiment of a second embodiment of the present disclosure.

FIG. 8 schematically illustrates a top view of an electronic device according to some embodiments of the present disclosure.

FIG. 9 schematically illustrates a cross-sectional view of an electronic device according to a second modified embodiment of a second embodiment of the present disclosure.

FIG. 10 schematically illustrates a top view of an electronic device according to a third embodiment of the present disclosure.

FIG. 11 schematically illustrates a cross-sectional view of an electronic device according to a fourth embodiment of the present disclosure.

FIG. 12 schematically illustrates a cross-sectional view of an electronic device according to a first modified embodiment of a fourth embodiment of the present disclosure.

FIG. 13 schematically illustrates a cross-sectional view of an electronic device according to a second modified embodiment of a fourth embodiment of the present disclosure.

FIG. 14 schematically illustrates a cross-sectional view of an electronic device according to a fifth embodiment of the present disclosure.

FIG. 15 schematically illustrates a cross-sectional view of an electronic device according to a sixth embodiment of the present disclosure.

FIG. 16 schematically illustrates a cross-sectional view of an electronic device according to a modified embodiment of a sixth embodiment of the present disclosure.

FIG. 17 schematically illustrates a cross-sectional view of an electronic device according to a seventh embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and elements therein may not be drawn to scale. The numbers and sizes of the elements in the drawings are just illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. It does not mean that the element has any previous ordinal numbers, nor does it represent the order of a certain element and another element, or the sequence in a manufacturing method. These ordinal numbers are just used to make a claimed element with a certain name be clearly distinguishable from another claimed element with the same name.

Spatially relative terms, such as “above”, “on”, “beneath”, “below”, “under”, “left”, “right”, “before”, “front”, “after”, “behind” and the like, used in the following embodiments just refer to the directions in the drawings and are not intended to limit the present disclosure.

In addition, when one element or layer is “on” or “above” another element or layer, it may be understood that the element or layer is directly on the another element or layer, and alternatively, another element or layer may be between the element or layer and the another element or layer (indirectly). On the contrary, when the element or layer is “directly on” the another element or layer, it may be understood that there is no intervening element or layer between the element or layer and the another element or layer. When one element or layer is “connected to” another element or layer, it may be understood that the element or layer is directly connected to the another element or layer or connected to the another element or layer through another element or layer (indirectly). On the contrary, when the element or layer is “directly connected to” the another element or layer, it may be understood that there is no another element or layer connected between the element or layer and the another element or layer.

As disclosed herein, the terms “approximately”, “equal”, “same”, “identical”, “essentially”, “about”, or “substantially” generally mean within 20%, 10%, 5%, 3%, 2%, 1%, or 0.5% of the reported numerical value or range. The quantity disclosed herein is an approximate quantity, that is, without a specific description of “approximately”, “equal”, “same”, “identical”, “essentially”, “about”, or “substantially”, the quantity may still include the meaning of “approximately”, “equal”, “same”, “identical”, “essentially”, “about”, or “substantially”.

It should be understood that according to the following embodiments, features of different embodiments may be replaced, recombined or mixed to constitute other embodiments without departing from the spirit of the present disclosure. The features of various embodiments may be mixed arbitrarily and used in different embodiments without departing from the spirit of the present disclosure or conflicting.

In the present disclosure, the length, thickness, width, height, distance, and area may be measured by using an optical microscope (OM), an electron microscope, such as a scanning electron microscope (SEM), or other approaches, but not limited thereto.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

An electronic device of the present disclosure may, for example, include a display device, a sensing device, an antenna device, a touch device, a tiled device, other suitable devices, or any combination of the aforementioned devices, but not limited thereto. The electronic device of the present disclosure may, for example, be a non-bendable, bendable, stretchable, foldable, rollable, or flexible electronic device, but not limited thereto. The display device may, for example, be applied to a laptop, a public display, a tiled display, a car display, a touch display, a television, a monitor, a smartphone, a tablet, a light source module, an illumination equipment, or an electronic device applied to the above-mentioned product, but not limited thereto. The sensing device may, for example, be a sensing device used for detecting variation in capacitances, light, heat, or ultrasound, but not limited thereto. The sensing device may, for example, include a biosensor, a touch sensor, a fingerprint sensor, other suitable sensors, or any combination of sensors mentioned above. The display device may, for example, include light emitting diodes, a fluorescent material, a phosphor material, other suitable display medium, or any combination of the above-mentioned display medium, but not limited thereto. The light emitting diode may, for example, include an organic light emitting diode (OLED), a mini light emitting diode (mini LED), a micro light emitting diode (micro LED), a quantum dot light emitting diode (e.g., QLED or QDLED), other suitable materials, or any combination of the above-mentioned material, but not limited thereto. The antenna device may, for example, include liquid crystal antenna or antennas of other types, but not limited thereto. The tiled device may, for example, include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems such as a driving system, a control system, a light source system, a shelf system, etc. The electronic device may include electronic units, in which the electronic units may include a passive element and an active element, and for example include a capacitor, a resistor, an inductor, a diode, a transistor, a sensor, etc. It is noted that the electronic device of the present disclosure may be any combination of the above-mentioned devices, but not limited thereto. The following contents and drawings take the display device as an example of the electronic device to detail the present disclosure, but the present disclosure is not limited herein.

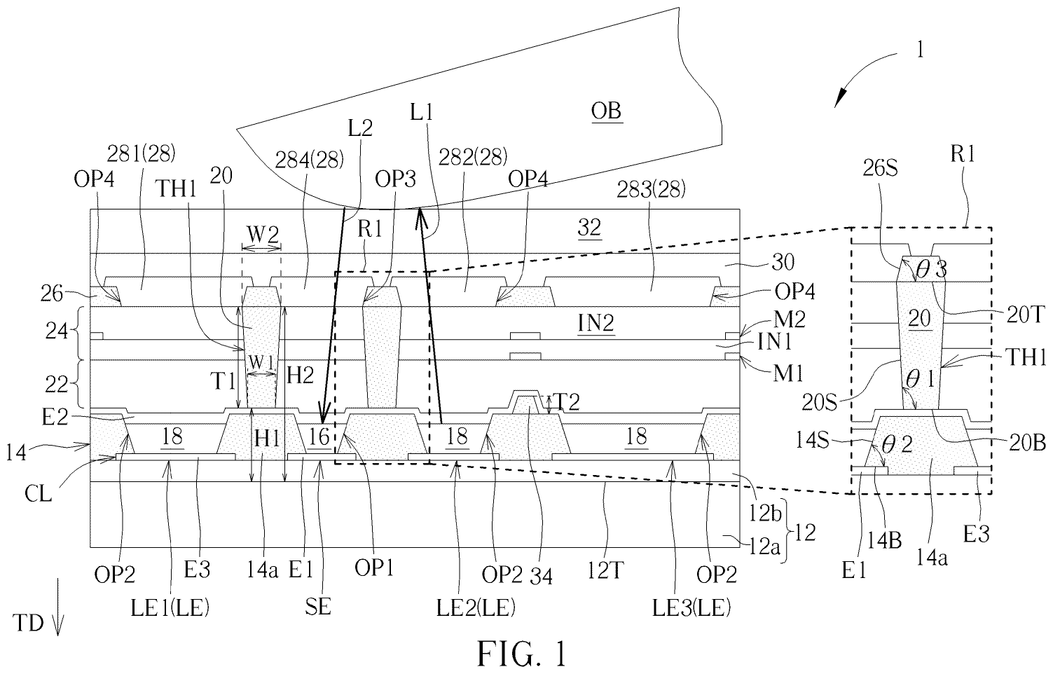

FIG. 1 schematically illustrates a cross-sectional view of an electronic device according to a first embodiment of the present disclosure. As shown in FIG. 1, an electronic device 1 includes a circuit substrate 12, a partition layer 14, a light receiving layer 16, a light emitting layer 18, and a light blocking pattern 20. The partition layer 14 is disposed on the circuit substrate 12 and includes an opening OP1, an opening OP2, and a partition wall 14a located between the opening OP1 and the opening OP2. Also, the light receiving layer 16 is disposed in the opening OP1, the light emitting layer 18 is disposed in the opening OP2, and the light blocking pattern 20 is disposed on the partition wall 14a. It is worth noting that for the light blocking pattern 20 is disposed on the partition wall 14a between the light receiving layer 16 and the light emitting layer 18, light L1 emitted by the light emitting layer 18 may be blocked by the light blocking pattern 20, which reduces or prevents the light L1 of the light emitting layer 18 from entering the light receiving layer 16 without shining on an object OB to be detected, such that a signal to noise ratio (SNR) of a light signal received by the light receiving layer 16 may be enhanced. In the present disclosure, light emitted by the light emitting layer 18 entering the light receiving layer 16 without shining on the object OB to be detected may be called stray light. The object OB to be detected may, for example, be a fingerprint or other suitable biometric characteristics.

Furthermore, in the cross-sectional view of the electronic device 1, the light blocking pattern 20 has a first width W1 at a first height H1 and has a second width W2 at a second height H2, wherein the second height H2 is higher than the first height H1, and the first width W1 is different from the second width W2. In the embodiment of FIG. 1, the second width W2 may be greater than the first width W1. Under this circumstance, as shown in an enlarged view of a region R1 in FIG. 1, an angle θ1 between a sidewall 20S of the light blocking pattern 20 and a bottom surface 20B of the light blocking pattern 20 facing the partition wall 14a may be greater than 90 degrees. Therefore, as light L2 is emitted toward the sidewall 20S of the light blocking pattern 20 from above the light blocking pattern 20 with a larger incident angle, the light L2 may be reflected downward by the light blocking pattern 20, and then, may enter the light receiving layer 16. It can be seen that by the design of the first width W1 less than the second width W2, a range of the incident angle of the light L2 received by the light receiving layer 16 may be increased, such that an intensity of the received light signal may be increased. For example, as the electronic device 1 has a high resolution, an area of the opening OP1 may decrease, such that the light is not easily to be received by the light receiving layer 16. By the aforementioned design, it may help the light to be collimated to enhance the received light signal of the light receiving layer 16. The “incident angle” mentioned herein may, for example, be an angle between an incident direction and a top view direction TD of the electronic device 1.

The light blocking pattern 20 may include light blocking material, such as including but not limited to colored organic and/or inorganic material, metal, transparent material with its surface coated with non-transparent material, or other suitable materials. The colored organic and/or inorganic material may, for example, include white, gray, black, or other suitable colors. The organic material may, for example, include photoresist material, acrylic material, silicon-based material, epoxy-based material, other suitable organic materials, or any combination of the above-mentioned materials, but not limited thereto. The acrylic material may, for example, be polymethyl methacrylate (PMMA), polyimide (PI), other suitable materials, or any combination of the aforementioned materials.

As shown in FIG. 1, the circuit substrate 12 may include a substrate 12a and a circuit layer 12b, wherein the circuit layer 12b may be disposed on the substrate 12a. The substrate 12a may, for example, include a rigid substrate or a flexible substrate. The rigid substrate may include glass, ceramic, quartz, sapphire, or other suitable materials, but not limited thereto. The flexible substrate may include PI, polyethylene terephthalate (PET), polycarbonate (PC), polyethersulfone (PES), polybutylene terephthalate (PBT), polyethylene naphthalate (PEN), polyarylate (PAR), other suitable materials, or any combination of the above-mentioned materials, but not limited thereto. In some embodiments, the substrate 12a may, for example, be a single-layered structure or a multi-layered structure. In some embodiments, as the substrate 12a includes the flexible substrate, the substrate 12a may optionally include a buffer layer disposed between the flexible substrate and the circuit layer 12b and used for reducing or preventing the circuit layer 12b, the light receiving layer 16, and/or the light emitting layer 18 from be affected by moisture and/or oxygen. The circuit layer 12b may, for example, include signal lines, insulating layers, active components, and/or passive components. The active components may, for example, include thin-film transistors or other suitable transistors, but not limited thereto. The signal lines may, for example, include data lines, scan lines, common lines, or other required signal lines.

In the present disclosure, the height is determined by setting an upper surface 12T of the substrate 12a to be a height datum plane with a height of zero. For example, the first height H1 may be a height of a bottom (e.g., the bottom surface 20B) of the light blocking pattern 20 relative to the upper surface 12T of the substrate 12a, which is the distance between the bottom of the light blocking pattern 20 and the upper surface 12T of the substrate 12a. The second height H2 may be a height of a top (e.g., an upper surface 20T) of the light blocking pattern 20 relative to the upper surface 12T of the substrate 12a, which is the distance between the top of the light blocking pattern 20 and the upper surface 12T of the substrate 12a. The height datum plane of the present disclosure may not be limited to the upper surface 12T of the substrate 12a. In addition, the top view direction TD may, for example, be parallel to a normal direction of the upper surface 12T of the substrate 12a. A top view of the electronic device in the following contents may be the electronic device viewed in the top view direction TD.

To be specific, as shown in FIG. 1, the electronic device 1 may include a light sensing element SE and a light emitting element LE, wherein the light emitting element LE may be used to emit light and the light sensing element SE may be used to detect the intensity of the light signal. The circuit layer 12b may be used to control if the light emitting element LE emits light, the emitted light intensity of the light emitting element LE, and/or readout of the light signal received by the light sensing element SE. The light sensing element SE may include a first electrode E1, the light receiving layer 16, and a second electrode. The light emitting element LE may include a third electrode E3, the light emitting layer 18, and a fourth electrode. In the embodiment of FIG. 1, the first electrode E1 and the third electrode E3 may be disposed on the circuit layer 12b and may be respectively electrically connected to the circuit layer 12b. The first electrode E1 and the third electrode E3 may be separated and electrically insulated from each other. The first electrode E1 and the third electrode E3 may, for example, include the same material or may be formed of a same conductor layer CL. The partition layer 14 is disposed on the first electrode E1 and the third electrode E3, wherein the opening OP1 and the opening OP2 of the partition layer 14 may respectively be overlapped with the first electrode E1 and the third electrode E3, such that the first electrode E1 and the third electrode E3 may be exposed respectively by the opening OP1 and the opening OP2. Also, the light receiving layer 16 may be disposed on the first electrode E1, and the second electrode may be disposed on the light receiving layer 16, such that the light receiving layer 16 may be electrically connected between the first electrode E1 and the second electrode. The light emitting layer 18 may be disposed on the third electrode E3, and the fourth electrode may be disposed on the light emitting layer 18, such that the light emitting layer 18 may be electrically connected between the third electrode E3 and the fourth electrode. In the present disclosure, an element “overlapped with” another element may be referred to as the element is overlapped with the another element in the normal direction of the upper surface 12T of the substrate 12a.

In the embodiment of FIG. 1, the second electrode and the fourth electrode may be formed of the same electrode E2. In other words, the electrode E2 may be disposed on both the light receiving layer 16 and the light emitting layer 18 and electrically connected to the light receiving layer 16 and the light emitting layer 18, such that a part of the electrode E2 corresponding to the light receiving layer 16 may be used as the second electrode of the light sensing element SE, and a part of the electrode E2 corresponding to the light emitting layer 18 may be used as the fourth electrode of the light emitting element LE. In an embodiment, the electrode E1 may be used as an anode of the light sensing element SE, the third electrode may be used as an anode of the light emitting element LE, and the electrode E2 may simultaneously be a cathode of the light sensing element SE and a cathode of the light emitting element LE and may be used to provide a common voltage, but not limited thereto. In some embodiments, the electrode E2 may be adjusted to be the anode of the light sensing element SE and the anode of the light emitting element LE according to the requirement from the circuit in practice, but not limited thereto. The electrode E2 may, for example, include metal, transparent conductive material, or other suitable materials. In the embodiment of FIG. 1, the electrode E2 may further be extended to be on the partition layer 14 and may be disposed between the partition wall 14a and the light blocking pattern 20, but not limited thereto.

In FIG. 1, the light receiving layer 16 of the light sensing element SE may include an organic photoelectric conversion material layer, but not limited thereto. The organic photoelectric conversion material layer may, for example, include polymer-based material or other suitable materials. In some embodiments, the light receiving layer 16 may include a positive-intrinsic-negative (PIN) semiconductor layer of an inorganic photodiode or other photoelectric conversion material that is able to convert photon energy into electrical energy. Alternatively, the light receiving layer 16 may include organic photodiode, inorganic photodiode, or other types of light receiving chip.

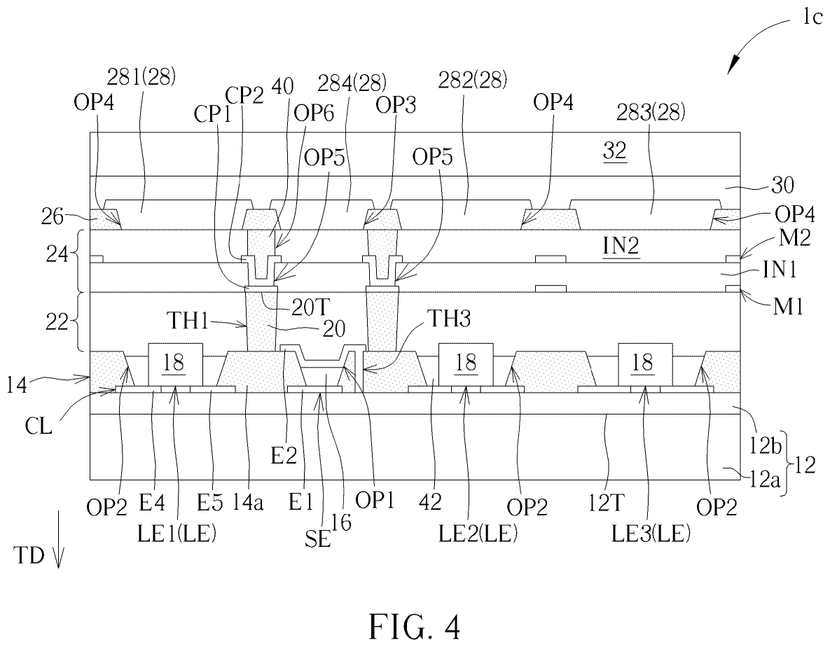

In the embodiment of FIG. 1, the light emitting layer 18 of the light emitting element LE may include organic light emitting material, such that the light emitting element LE may include an organic light emitting diodes (OLED), but not limited thereto. In some embodiments, the light emitting layer 18 may include the OLED, an inorganic light emitting diode, or other suitable materials. Alternatively, the light emitting layer 18 may, for example, include a mini light emitting diode (mini LED), a micro light emitting diode (micro LED), quantum dots (QDs), a quantum dot light emitting diode (e.g., QLED or QDLED), a nanowire LED, a bar type LED, a fluorescent material, a phosphor material, other suitable materials, or any combination of the above-mentioned materials, but not limited thereto. In some embodiments, the light emitting layer 18 may include a vertical type LED disposed between the third electrode E3 and the electrode E2. In this case, the electronic device 1 may optionally include an adhesive layer (e.g., the adhesive layer 42 shown in FIG. 4) disposed between the light emitting element LE and the partition layer 14 and used to fix the light emitting element LE in the corresponding opening OP2. The adhesive layer may, for example, surround the light emitting element LE. Type of LED in the present disclosure is not limited to the aforementioned contents.

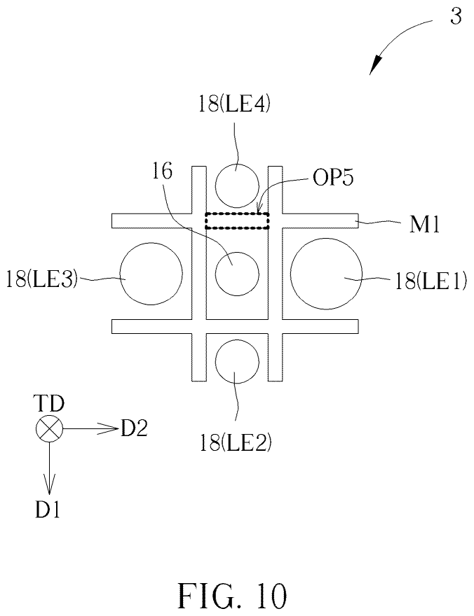

As shown in FIG. 1, the electronic device 1 may include a plurality of light emitting elements LE. That is, the partition layer 14 may include a plurality of openings OP2 and a plurality of partition walls 14a, wherein the light emitting layers 18 of the light emitting elements LE may individually be disposed in the corresponding openings OP2, and the partition walls 14a may be disposed between the light receiving layer 16 and the light emitting layer 18 and between the two adjacent light emitting layers 18. As the electronic device 1 is a display device, the partition layer 14 may, for example, be a pixel defining layer, and one of the openings OP2 may define a sub-pixel or a region of a pixel, but not limited thereto. Under this circumstance, the light emitting elements LE may be used as the sub-pixels or the pixels of the display device, but not limited thereto. For example, the light emitting elements LE may include a plurality of first light emitting elements LE1, a plurality of second light emitting elements LE2, and a plurality of third light emitting elements LE3 respectively used to emit light with a first color, light with a second color, and light with a third color, wherein the first color, the second color, and the third color are different from each other. The first color, the second color, and the third color may, for example, respectively be red, green, and blue or other suitable colors. At least one of the first light emitting elements LE1, at least one of the second light emitting elements LE2, and at least one of the third light emitting elements LE3 may form one of the pixels, such that the plurality of first light emitting elements LE1, the plurality of second light emitting elements LE2, and the plurality of light emitting elements LE3 may display an image, but not limited thereto. At least one of the first light emitting elements LE1, the second light emitting elements LE2, and the third light emitting elements LE3 may be used as a detection light source of the light sensing element SE. For example, the second light emitting element LE2 adjacent to the light sensing element SE may be used as the detection light source of the light sensing element SE, but not limited thereto. In some embodiments, the light emitting elements LE may further include a fourth light emitting element used as the detection light source of the sensing element SE, and the fourth light emitting element is not used for displaying the image, for example, as shown in FIG. 10.

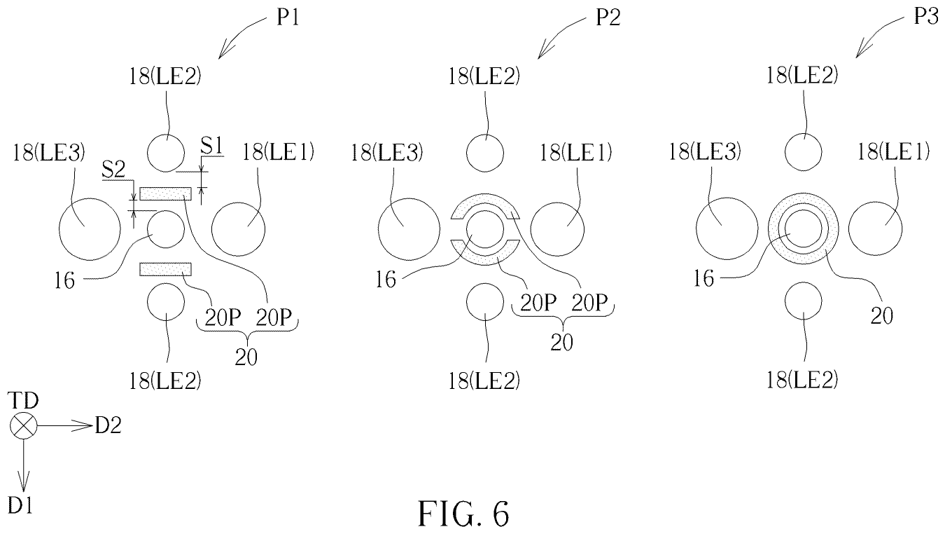

What needs to be clarified is that the electronic device 1 may be capable of operating in a display mode or a sense mode, wherein as the electronic device 1 is in the display mode, the first light emitting elements LE1, the second light emitting elements LE2, and the third light emitting elements LE3 may emit light in order to display the image. Alternatively, as the electronic device 1 is in the sense mode, one of the first light emitting elements LE1, the second light emitting elements LE2, and the third light emitting elements LE3 may emit the light L1. Through the aforementioned operation method, for the light blocking pattern 20 in the top view of the electronic device 1 is at least disposed between the light receiving layer 16 and the light emitting element LE (e.g., the second light emitting element LE2) used as detection light source in the light emitting layer 18, as the electronic device 1 is in the sense mode, the light blocking pattern 20 may block the light emitted by the second light emitting element LE2 from being directly emitted to the light sensing element SE, such that the SNR of the light signal may be enhanced. In the embodiment of FIG. 1, the light blocking pattern 20 in the top view of the electronic device 1 may, for example, surround the light receiving layer 16, but not limited thereto. In some embodiments, the light blocking pattern 20 may include a plurality of light blocking walls arranged around the light receiving layer 16, for example, the light blocking walls 20P shown in FIG. 6. The structure of the light blocking pattern 20 in the top view of the electronic device 1 may be the same as that of the light blocking pattern 20 shown in FIG. 6, but not limited thereto. In some embodiments, the arrangement of one of the first light emitting elements LE1, two of the second light emitting elements LE2, one of the third light emitting elements LE3, and the light sensing element SE of the light receiving layer 16 may, for example, be shown in FIG. 6, but not limited thereto.

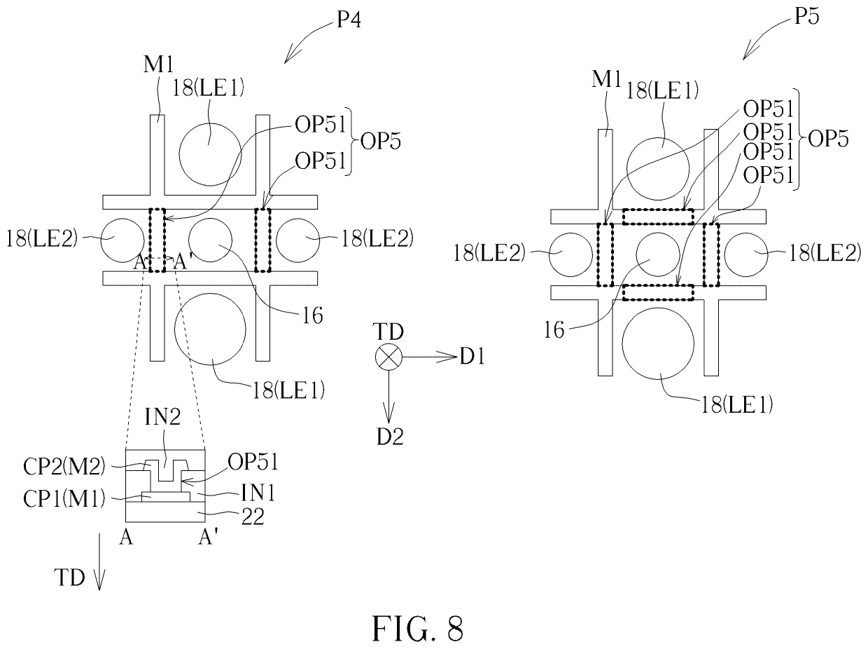

In some embodiments, the electronic device 1 may include a plurality of light sensing elements SE used to detect an image, such as a fingerprint image. By the light blocking pattern 20 blocking the stray light, an identification accuracy of the fingerprint image may be enhanced effectively. The partition layer 14 may include a plurality of openings OP1, and the light receiving layer 16 of the light sensing elements SE may respectively be disposed in the corresponding openings OP1. One of the light sensing elements SE may, for example, correspond to plural light emitting elements LE or one of the pixels, for example, shown in FIG. 6, FIG. 8, or FIG. 10, but not limited thereto.

In the embodiment of FIG. 1, the partition layer 14 may block light from passing through to reduce the noise of the light signal detected by the light sensing element SE. A material of the partition layer 14 and a material of the light blocking pattern 20 may be the same as or different from each other. In FIG. 1, the material of the partition layer 14 may be the same as the material of the light blocking pattern 20, and the partition layer 14 may include light blocking material. In some embodiment, as the material of the partition layer 14 is different from the material of the light blocking pattern 20, the partition layer 14 may include transparent organic material, and the light blocking pattern 20 may include the light blocking material.

In FIG. 1, the electronic device 1 may optionally include a spacer 34 disposed on the partition layer 14. In the top view of the electronic device 1, the spacer 34 may be separated from the light blocking pattern 20; for example, the spacer 34 may be disposed between two adjacent openings OP2. It is noted that in the formation of the light receiving layer 16 or the light emitting layer 18, a mask is required to be disposed on the circuit substrate 12, such that the light emitting layer 18 with a certain color may be formed in the predetermined opening OP2, or the light receiving layer 16 may be formed in the opening OP1. Consequently, the spacer 34 may be used to support the mask to reduce or prevent the circuit substrate 12 from being damaged by colliding with the mask. In an embodiment, a thickness T1 of the light blocking pattern 20 may be greater than a thickness T2 of the spacer 34. The thickness T1 of the light blocking pattern 20 may, for example, be greater than or equal to 1.2 micrometers (μm) and less than or equal to 12 μm. The thickness T2 of the spacer 34 may, for example, be less than 1 μm. The spacer 34 may, for example, include the same material as the light blocking pattern 20, but not limited thereto. In some embodiments, a ratio of the thickness T1 of the light blocking pattern 20 to a thickness of the partition layer 14 may, for example, be in the range of 1 to 10.

As shown in FIG. 1, the electronic device 1 may further include an encapsulation layer 22 disposed on the light sensing elements SE and the light emitting element LE in order to reduce the possibility of the light sensing elements SE and the light emitting element LE being damaged by moisture or oxygen. The encapsulation layer 22 may be further disposed on the partition layer 14, and the light blocking pattern 20 may be through the encapsulation layer 22. For example, the light blocking pattern 20 may be in contact with the electrode E2, such that the stray light may not pass through between the light blocking pattern 20 and the electrode E2, which enhances the SNR, but not limited thereto. In the present disclosure, when an element is “in contact with” another element, under the condition that the element and the another element include different materials, there may be a clear interface between the element and the another element. Alternatively, under the condition that the element and the another element include the same material, there may not be an interface between the element and the another element, and the interface between the element and the another element may be determined by the width difference between the element and the another element.

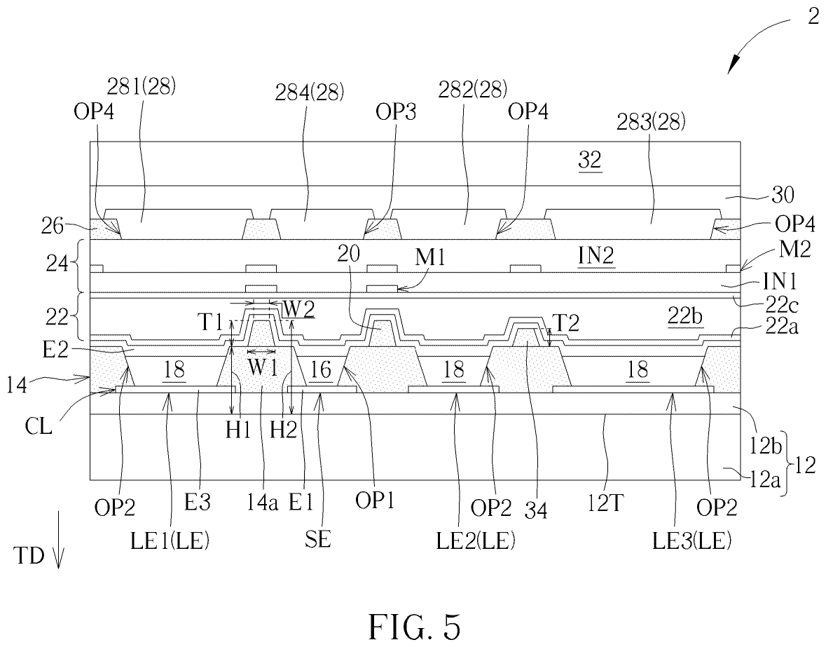

In an embodiment, the encapsulation layer 22 may include a stack of an inorganic material layer, an organic material layer, and an inorganic material layer (e.g., the inorganic material layer 22a, the organic material layer 22b, and the inorganic material layer 22c shown in FIG. 5), but not limited thereto. In some embodiments, the encapsulation layer 22 may include a stack of at least one inorganic material layer and at least one organic material layer or may include multiple inorganic material layers. The inorganic material layer may, for example, include silicon nitride, silicon oxide, silicon oxynitride, aluminum oxide, other suitable protective materials, or any combination of the above-mentioned inorganic materials, but not limited thereto. Different inorganic material layers may include the same or different material. The organic material layer may have an effect of flattening its upper surface; for example, the organic material layer may include resin or other suitable materials, but not limited thereto.

As shown in FIG. 1, the electronic device 1 may further include a sensing layer 24 disposed on the encapsulation layer 22, and the light blocking pattern 20 may be through the sensing layer 24, but not limited thereto. The sensing layer 24 may at least include a conductor layer used for forming a touch sensing element. The touch sensing element may, for example, be used to detect a position of a touching object contacting or close to the electronic device 1. The touching object may, for example, include fingers, a stylus pen, or other suitable objects. In an embodiment, the sensing layer 24 may be disposed on the partition layer 14 and may include a metal layer M1, a metal layer M2, and an insulating layer IN1, wherein the insulating layer IN1 is disposed between the metal layer M1 and the metal layer M2. In FIG. 1, the metal layer M1, the insulating layer IN1, and the metal layer M2 may be sequentially formed on the encapsulation layer 22, but not limited thereto. In some embodiments, the metal layer M1 and/or the metal layer M2 may, for example, include a mesh structure. The mesh structure may be, for example, as shown in FIG. 8 or FIG. 10. Here will be no further elaborations due to the configuration of using the metal mesh structure to form the touch sensing element is known to whom is skilled in the art. In some embodiments, the sensing layer 24 may further include an insulating layer IN2 disposed on the metal layer M2, but not limited thereto. The insulating layer IN1 and the insulating layer IN2 may, for example, include silicon nitride, silicon oxide, silicon oxynitride, or other suitable insulating materials. In the embodiment of FIG. 1, the metal layer M1 and the metal layer M2 are not overlapped with the light blocking pattern 20, but not limited thereto.

In the embodiment of FIG. 1, the encapsulation layer 22 and the sensing layer 24 may include a through hole TH1, and the light blocking pattern 20 is disposed in the through hole TH1, such that the light blocking pattern 20 may penetrate through the encapsulation layer 22 and the sensing layer 24. By this design, the light blocking pattern 20 may shield light emitted by the second light emitting element LE2 from being emitted to the light sensing element SE through the sensing layer 24 and the encapsulation layer 22, such that the SNR may be enhanced. The upper surface 20T of the light blocking pattern 20 may be flat, but not limited thereto. In some embodiments, the upper surface 20T of the light blocking pattern 20 may be a recess surface in the through hole TH1 or a protrusion surface that protrudes out the through hole TH1.

As shown in FIG. 1, the electronic device 1 may further include a black matrix 26 and a plurality of color filters 28 disposed on the sensing layer 24 and the light blocking pattern 20. The color filters 28 and the black matrix 26 may be used as an anti-reflection layer to reduce effect of ambient light on a contrast ratio of the image displayed by the electronic device 1. In the embodiment of FIG. 1, the black matrix 26 may be overlapped with the partition layer 14. In the embodiment of FIG. 1, the black matrix 28 may be in contact with the light blocking pattern 20, such that the stray light may not pass through between the light blocking pattern 20 and the black matrix 26, which enhances the SNR.

In FIG. 1, the black matrix 26 may include at least one opening OP3 and a plurality of openings OP4, wherein the opening OP3 may be overlapped with the opening OP1, and the openings OP4 may respectively be overlapped with the openings OP2. In the embodiment of FIG. 1, the color filters 28 may, for example, include a first color filter 281, a second color filter 282, a third color filter 283, and a fourth color filter 284, wherein the fourth color filter 284 may be disposed in the opening OP3, and the first color filter 281, the second color filter 282, and the third color filter 283 may respectively be disposed in the openings OP4. The first color filter 281, the second color filter 282, and the third color filter 283 may respectively include the first color, the second color, and the third color that are different from each other. The first color filter 281, the second color filter 282, and the third color filter 283 may be respectively overlapped with the first light emitting element LE1, the second light emitting element LE2, and the third light emitting element LE3, but not limited thereto. The first color filter 281, the second color filter 282, and the third color filter 283 with different colors may reduce a brightness of the ambient light passing through one of the first color filter 281, the second color filter 282, and the third color filter 283 and being reflected by the circuit substrate 12 to be emitted out from another one of the first color filter 281, the second color filter 282, and the third color filter 283, such that it may reduce effect of the ambient light on the contrast ratio of the image displayed by the electronic device 1.

In an embodiment, the fourth color filter 284 may, for example, have the same color as that of one of the first color filter 281, the second color filter 282, and the third color filter 283, such that the noise of the light signal detected by the light sensing element SE may be reduced. The color of the fourth color filter 284 may have the same color as that of the color filter 28 corresponding to the light emitting element LE used as the detection light source, for example, may have the same color as the color of the second color filter 282, but not limited thereto.

As shown in FIG. 1, the electronic device 1 may further include a protective layer 30 and a covering layer 32 sequentially disposed on the black matrix 26 and the color filter 28. The protective layer 30 may include an organic material, such as photoresist material, PI, PET, adhesive glue, or other suitable materials. The covering layer 32 may be attached to the protective layer 30 by an adhesive layer. The covering layer 32 may, for example, include glass or other suitable materials. In some embodiments, there may optionally be a hard coating layer disposed on the covering layer 32. Or, the covering layer 32 may optionally include an ultra-thin glass (UTG) and a hard coating layer, wherein the hard coating layer is disposed on the UTG, but not limited thereto. The hard coating layer may, for example, include polycarbonate (PC), acrylic, or other suitable materials.

The following content will further clarify the manufacturing method of the electronic device 1 of this embodiment. As shown in FIG. 1, a substrate 12a is provided first, and then, the circuit layer 12b and the conductor layer CL are formed. The method of forming the circuit layer 12b and the conductor layer CL may, for example, include a thin-film process, a deposition process, a photolithography and etching process, or other suitable processes. Afterwards, the partition layer 14 is formed on the circuit layer 12b and the conductor layer CL, wherein the partition layer 14 may form the opening OP1 and the openings OP2 through a patterning process. Then, the light receiving layer 16 is formed in the opening OP1 and the light emitting layers 18 are formed in the openings OP2, respectively, wherein the light emitting layers 18 of the light emitting elements LE with different colors may be formed separately. The steps of forming the light receiving layer 16 and forming the light emitting layers 18 with different colors may be interchangeable. The method of forming the light receiving layer 16 and the light emitting layers 18 may, for example, include an evaporation process or other suitable processes. Following that, the electrode E2 is formed on the partition layer 14, the light receiving layer 16, and the light emitting layers 18, and the encapsulation layer 22 and the sensing layer 24 are sequentially formed on the electrode E2. Next, the through hole TH1 is formed in the insulating layer IN1 and insulating layer IN2 of the sensing layer 24 and the encapsulation layer 22, such that the electrode E2 is exposed. The method of forming the through hole TH1 may, for example, include laser drilling, dry etching, wet etching, or any combination of the above-mentioned processes. Then, the light blocking pattern 20 is formed in the through hole TH1 by a filling process. The method of forming the light blocking pattern 20 may, for example, include disposing the light blocking material into the through hole TH1 by using inkjet printing process, coating the light blocking material blanketly in combination with removing the light blocking material outside the through hole TH1, or other suitable filling processes. In the embodiment of FIG. 1, the light blocking pattern 20 is a single-layered structure, but not limited thereto. In some embodiments, the light blocking pattern 20 may, for example, include at least two light blocking layers sequentially stacked in the through hole TH1. For example, the light blocking layers may be formed sequentially in the through hole TH1 by the filling processes after the through hole TH1 is formed.

It is noted that for the light blocking pattern 20 is formed in the through hole TH1, the first width W1 may be less than the second width W2. The opening OP1 and the openings OP2 of the partition layer 14 may be formed by an etching process, so that an angle θ2 between a sidewall 14S of the partition wall 14a and a bottom surface 14B of the partition wall 14a facing the first electrode E1 (or the third electrode E3) of the conductor layer CL may be less than the angle θ1 between the sidewall 20S of the light blocking pattern 20 and the bottom surface 20B of the light blocking pattern 20, for example, less than 90 degrees.

As shown in FIG. 1, after forming the light blocking pattern 20, the black matrix 26 may be formed on the sensing layer 24 and the light blocking pattern 20. The opening OP3 and the openings OP4 of the black matrix 26 may, for example, be formed by a patterning process. Next, the color filters 28 may be formed in the opening OP3 and the openings OP4. Thereafter, the protective layer 30 is formed on the black matrix 26 and the color filters 28, and the cover layer 32 is attached to the protective layer 30, thereby forming the electronic device 1 of this embodiment. As shown in an enlarged view of the region R1 in FIG. 1, an angle θ3 between a sidewall 26S of the black matrix 26 and the upper surface 20T of the light blocking pattern 20 may be different from the angle θ2 and the angle θ1, but not limited thereto.

In some embodiments, the color filters 28 may be formed on the sensing layer 24 and the light blocking pattern 20 before the black matrix 26 is formed, such that two adjacent color filters 28 with different colors may partially be overlapped with each other, and an overlapping part of them may be overlapped with the partition layer 14, but not limited thereto. In this way, an upper surface of the black matrix 26 may be an arc surface, but not limited thereto.

The electronic device of the present disclosure is not limited to the above mentioned embodiments and may have other embodiments or modified embodiments. To simplify description, other embodiments and modified embodiments in the following contents will use the same notations to the same elements from the aforementioned embodiments. To clearly clarify other embodiments and modified embodiments, the following contents will emphasize on the difference between other embodiments and modified embodiments and the aforementioned embodiments, and will not further elaborate for the repeated part.

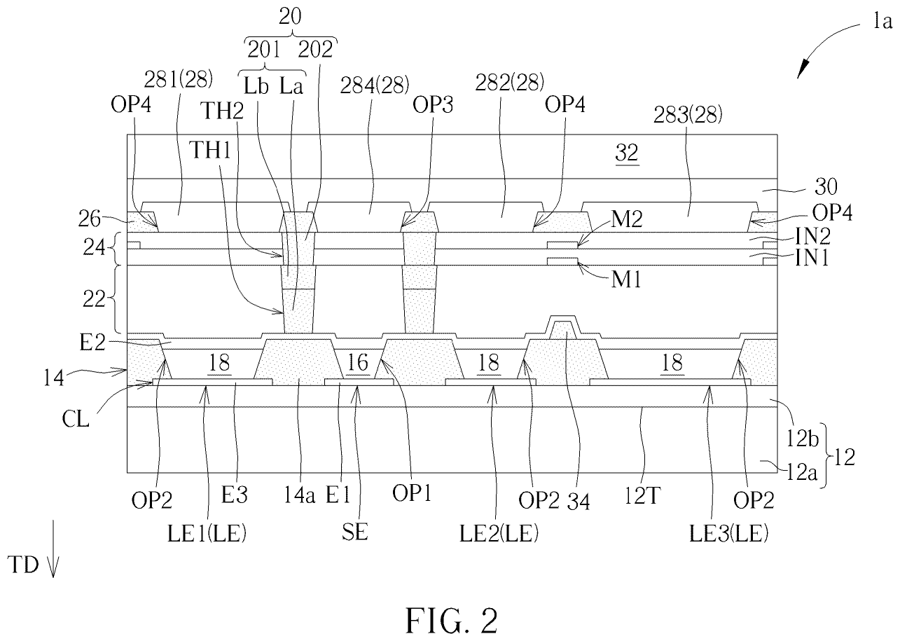

Refer to FIG. 2. FIG. 2 schematically illustrates a cross-sectional view of the electronic device according to a first modified embodiment of the first embodiment of the present disclosure. As shown in FIG. 2, a difference between the electronic device 1a of this modified embodiment and the electronic device 1 of the aforementioned embodiment is that the light blocking pattern 20 may include a first sub-layer 201 and a second sub-layer 202, wherein the first sub-layer 201 may be through the encapsulation layer 22, and the second sub-layer 202 may be through the sensing layer 24. In the embodiment of FIG. 2, the encapsulation layer 22 may include the through hole TH1, and the first sub-layer 201 may be disposed in the through hole TH1. The sensing layer 24 may include a through hole TH2, and the second sub-layer 202 may be disposed in the through hole TH2. Because the through hole TH1 and the through hole TH2 are formed separately, the first sub-layer 201 and the second sub-layer 202 may form a step structure, but not limited thereto. For example, in the manufacturing method of the electronic device 1a of this modified embodiment, after the encapsulation layer 22 is formed, the through hole TH1 penetrating through the encapsulation layer 22 may be formed, and then, the first sub-layer 201 is formed in the through hole TH1. Next, the sensing layer 24 is formed on the encapsulation layer 22 and the first sub-layer 201, and the through hole TH2 penetrating through the sensing layer 24 is formed. Then, the second sub-layer 202 is formed in the through hole TH2, thereby forming the light blocking pattern 20 of this modified embodiment. For other parts of the electronic device 1a and other steps of the manufacturing method of the electronic device 1a of this modified embodiment may be identical or similar to the aforementioned embodiment, and therefore, will not be redundantly detailed.

In the modified embodiment of FIG. 2, the step of forming the first sub-layer 201 may optionally include performing a plurality of filling processes, such that the first sub-layer 201 may have a multi-layered structure, for example, including a sub-layer La and a sub-layer Lb sequentially stacked in the through hole TH1, but not limited thereto. In some embodiments, the number of the sub-layers of the first sub-layer 201 may not be limited to two layers and may be three or more layers. In some embodiments, the second sub-layer 202 may have a multi-layered structure. Or, the light blocking pattern 20 may include sub-layers with two or more layers respectively disposed in two or more through holes. In some embodiments, the step of forming the first sub-layer 201 may perform one filling process, such that the first sub-layer 201 may be a single-layered structure, but not limited thereto.

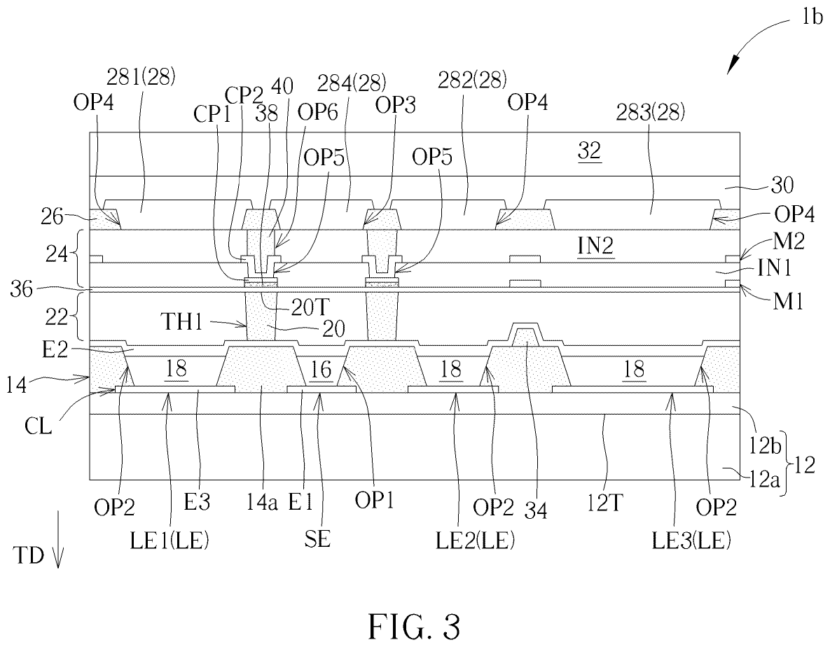

Refer to FIG. 3. FIG. 3 schematically illustrates a cross-sectional view of the electronic device according to a second modified embodiment of the first embodiment of the present disclosure. As shown in FIG. 3, a difference between the electronic device 1b and the electronic device 1 of the above-mentioned embodiment is that the light blocking pattern 20 may penetrate through the encapsulation layer 22 but not be disposed in the sensing layer 24. In the modified embodiment of FIG. 3, the insulating layer IN1 of the sensing layer 24 may include at least one opening OP5, the metal layer M2 may penetrate through the opening OP5 and may be connected to the metal layer M1, and the opening OP5 may be overlapped with the light blocking pattern 20. To be specific, the metal layer M1 may include at least one connecting part CP1, and the metal layer M2 may include at least one connecting part CP2, wherein the connecting part CP2 may be extended to the opening OP5 to be connected to the connecting part CP1. In this way, the connecting part CP1 and the connecting part CP2 may reduce or prevent the stray light from being emitted to the light receiving layer 16 through the insulating layer IN1. It is noted that, in some cases, for example, as the distribution density of the light sensing elements SE increases, the connection between the connecting part CP1 and the connecting part CP2 may enhance touch sensitivity of the sensing layer 24. In some embodiments, the connecting part CP1 of the metal layer M1 may be in contact with the light blocking pattern 20 in order to reduce or prevent the stray light from passing through between the connecting part CP1 and the light blocking pattern 20.

In some embodiments, as shown in FIG. 3, the electronic device 1b may further include a flattening layer 36 disposed between the light blocking pattern 20 and the sensing layer 24 and between the encapsulation layer 22 and the sensing layer 24. Because the upper surface 20T of the light blocking pattern 20 may not be a flat surface, the uneven upper surface 20T of the light blocking pattern 20 may reduce or prevent the sensing layer 24 from being affected during forming the sensing layer 24, thereby enhance quality of the sensing layer 24.

In some embodiments, as shown in FIG. 3, the electronic device 1b may further include another light blocking pattern 38 disposed under the metal layer M1, wherein the light blocking pattern 38 is overlapped with the opening OP5. Under this condition, the light blocking pattern 38 may, for example, include black metal or black polymer material, such that the light blocking pattern 38 may have an anti-reflection surface, which reduces or prevents the stray light from being emitted to the light receiving layer 16 after being reflected by the metal layer M1. The polymer material may, for example, include resin or other suitable materials.

In some embodiments, as shown in FIG. 3, the electronic device 1b may further include another light blocking pattern 40 disposed on the metal layer M2, and the light blocking pattern 40 may be overlapped with the opening OP5. For example, the insulating layer IN2 may include an opening OP6 exposing the metal layer M2, and the light blocking pattern 40 may be disposed in the opening OP6 to be in contact with the metal layer M2. Under this circumstance, the light blocking pattern 40 may further reduce or prevent the stray light from being emitted to the light receiving layer 16 through the insulating layer IN2. In some embodiments, the black matrix 26 may further be in contact with the light blocking pattern 40, but not limited thereto. The light blocking pattern 40 may, for example, include the same material as that of the light blocking pattern 20, but not limited thereto. In some embodiments, the black matrix 26 and the light blocking pattern 40 may be formed of the same light blocking layer, but not limited thereto. For other parts of the electronic device 1b and other steps of the manufacturing method of the electronic device 1b in this modified embodiment may be identical or similar to the aforementioned embodiments, and therefore, will not be redundantly detailed.

Refer to FIG. 4. FIG. 4 schematically illustrates a cross-sectional view of the electronic device according to a third modified embodiment of the first embodiment of the present disclosure. As shown in FIG. 4, a difference between the electronic device 1c and the electronic device 1b of the aforementioned modified embodiment is that the light emitting layer 18 of the light emitting element LE may include a flip chip type LED. In other words, the light emitting element LE may be a LED chip. Under this condition, the conductor layer CL may include a plurality of electrode pairs, wherein each of the electrode pairs may include an electrode E4 and an electrode E5, and two ends of each of the light emitting elements LE may be disposed on the corresponding electrode E4 and the corresponding electrode E5 and electrically connected to the circuit layer 12b through the corresponding electrode E4 and the corresponding electrode E5, respectively. In the embodiment of FIG. 4, the electrode E2 may not be disposed on the light emitting layers 18 and may be disposed on the light receiving layer 16. In addition, the partition layer 14 may include a through hole TH3 exposing the circuit layer 12b, and the electrode E2 may be electrically connected to the circuit layer 12b through the through hole TH3; for example, the electrode may be extended to the through hole TH3.

In the embodiment of FIG. 4, the electronic device 1c may optionally further include an adhesive layer 42 disposed between the light emitting elements LE and the partition layer 14 and used to fix the light emitting elements LE in the corresponding openings OP2, but not limited thereto. The adhesive layer 42 may, for example, surround each light emitting element LE. The adhesive layer 42 may, for example, include transparent or non-transparent adhesive material or other suitable materials.

In FIG. 4, the light blocking pattern 20 may be in contact with the metal layer M1 of the sensing layer 24, but not limited thereto. In some embodiments, the electronic device 1c may optionally include the flattening layer 36 in FIG. 3 disposed between the light blocking pattern 20 and the sensing layer 24. Under this condition, the electronic device 1c may optionally further include the light blocking pattern 38 in FIG. 3 disposed under the metal layer M1. For other parts of the electronic device 1c and other steps of the manufacturing method of the electronic device 1c in this modified embodiment may be identical or similar to the aforementioned embodiment, and therefore, will not be redundantly detailed.

Refer to FIG. 5. FIG. 5 schematically illustrates a cross-sectional view of the electronic device according to a second embodiment of the present disclosure. As shown in FIG. 5, a difference between the electronic device 2 of this embodiment and the electronic devices of the aforementioned embodiments is that the second width W2 of the light blocking pattern 20 at the second height H2 may be less than the first width W1 of the light blocking pattern 20 at the first height H1. Under this circumstance, as light with a larger incident angle being emitted from above the light blocking pattern 20 to the sidewall of the light blocking pattern 20, the light may be reflected upward by the light blocking pattern 20, such that a range of the incident angle of light receiving by the light receiving layer 16 may be shrunk. Hence, light with larger incident angle may be filtered out, which reduces the stray light received by the receiving layer 16 to enhance the SNR.

In the embodiment of FIG. 5, the electrode E2 may be disposed on the light blocking pattern 20. For the light blocking pattern 20 may be formed on the partition layer 14 before forming the electrode E2, the light blocking pattern 20 may, for example, be in contact with the partition layer 14, but not limited thereto. In this case, the encapsulation layer 22 is formed after the electrode E2 is formed. Hence, the encapsulation layer 22 may not include any through holes, such that the protection to the light receiving layer 16 and the light emitting layers 18 may be enhanced. In some embodiments, for the light blocking pattern 20 in FIG. 5 does not penetrate through the encapsulation layer 22 and the sensing layer 24, at least one of the metal layer M1 and the metal layer M2 may be overlapped with the light blocking pattern 20, but not limited thereto.

In the embodiment of FIG. 5, the thickness T1 of the light blocking pattern 20 may be greater than the thickness T2 of the spacer 34. The thickness T1 of the light blocking pattern 20 may, for example, be greater than or equal to 1.2 μm and less than or equal to 12 μm. The thickness T2 of the spacer 34 may, for example, be less than 1 μm. The measurement of the “thickness” mentioned herein may take a comparatively flat position (e.g., the position of the upper surface of the light blocking pattern 20) as the datum plane to measure the thickness T1 of the light blocking pattern 20 and the thickness T2 of the spacer 34, but not limited thereto. For other parts of the electronic device 2 and other steps of the manufacturing method of the electronic device 2 of this embodiment may be identical or similar to the aforementioned embodiment, and therefore, will not be redundantly detailed.

Refer to FIG. 6. FIG. 6 schematically illustrates a top view of the electronic device according to some embodiments of the present disclosure. As shown in a part P1 to a part P3 of FIG. 6, the second light emitting elements LE2 of some embodiments may be used as the light source of the light receiving layer 16. Under this condition, as shown in the part P1 and the part P2 of FIG. 6, the light blocking pattern 20 of some embodiments may include the two light blocking walls 20P respectively disposed between the light receiving layer 16 and the light emitting layers 18 of the corresponding second light emitting elements LE2. Furthermore, the light emitting layers 18 of the second light emitting elements LE2 and the light receiving layer 16 may be arranged in a first direction D1, and in a second direction D2 perpendicular to the first direction D1, the width of one of the light blocking walls 20P may be greater than the width of the light receiving layer 16 and/or the width of one of the light emitting layers 18, but not limited thereto. A top-view shape of one of the light blocking walls 20P may, for example, be strip or arc. In the part P2 of FIG. 6, the light blocking walls 20P may be arranged around the light receiving layer 16. As shown in the part P3 of FIG. 6, the light blocking pattern 20 of some embodiments may surround the light receiving layer 16. In the present disclosure, the term “surround” may not be limited to continuously encircle as shown in the part P2 of FIG. 6 and may be referred to as discontinuously encircle as shown in the part P1 and the part P3 of FIG. 3. A top-view structure of the light blocking pattern 20 in any one of the part P1, the part P2, and the part P3 of FIG. 6 may be applied to the light blocking pattern of any of the above-mentioned and the following embodiments. It is noted that, in the top view of this specification, the top-view outline of the light receiving layer 16 may be referred to as a top-view range of an upper surface of the light receiving layer 16, and the top-view outline of the light emitting layer 18 may be referred to as a top-view range of the upper surface of the light emitting layer 18, but not limited thereto.

In some embodiments, a distance S1 between one of the light blocking walls 20P and the corresponding light emitting layer 18 may be greater than a distance S2 between the light blocking wall 20P and the light receiving layer 16 to enhance the collimating effect, but not limited thereto. In some embodiments, the distance S1 between the light blocking wall 20P and the corresponding light emitting layer 18 may be less than the distance S2 between the light blocking wall 20P and the light receiving layer 16.

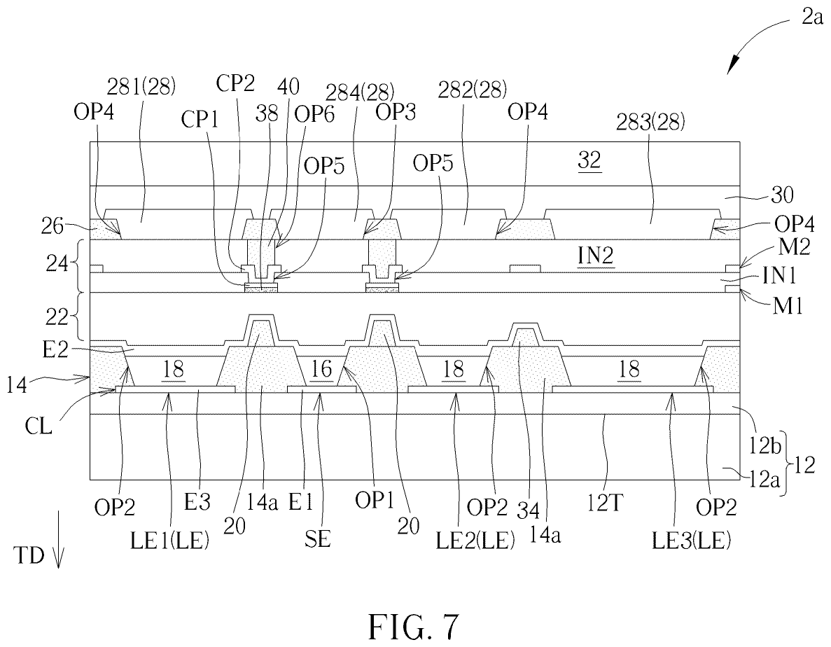

Refer to FIG. 7. FIG. 7 schematically illustrates a cross-sectional view of the electronic device according to a first modified embodiment of the second embodiment of the present disclosure. As shown in FIG. 7, a difference between the electronic device 2a of this modified embodiment and the electronic device 2 of FIG. 5 is that the insulating layer IN1 of the sensing layer 24 may include the opening OP5, and the metal layer M2 may penetrate through the opening OP5 and may be connected to the metal layer M1, wherein the opening OP5 may be overlapped with the light blocking pattern 20. To be specific, the metal layer M1 may include the at least one connecting part CP1, the metal layer M2 may include the at least one connecting part CP2, and the connecting part CP2 may be extended to the opening OP5 to be connected to the connecting part CP1. In this way, the connecting part CP1 and the connecting part CP2 may reduce or prevent the stray light from being emitted to the light receiving layer 16 through the insulating layer IN1. Because the connecting part CP1 and the connecting part CP2 may be overlapped with the light blocking pattern 20, the metal layer M1 and the metal layer M2 may not have to be separated from the light blocking pattern 20 in the top view, such that the touch sensitivity of the light sensing layer 24 may be enhanced.

In some embodiments, as shown in FIG. 7, the electronic device 2a may include the light blocking pattern 38 disposed under the metal layer M1, wherein the light blocking pattern 38 is overlapped with the opening OP5. The light blocking pattern 38 of this modified embodiment may be similar to or identical to the light blocking pattern 38 of FIG. 3, and therefore, will not be redundantly detailed.

In some embodiments, the electronic device 2a may further include the light blocking pattern 40 disposed on the metal layer M2, and the light blocking pattern 40 may be overlapped with the opening OP5. For example, the insulating layer IN2 may include the opening OP6 exposing the metal layer M2, and the light blocking pattern 40 may be disposed in the opening OP6 to be in contact with the metal layer M2. Under this circumstance, the light blocking pattern 40 may further reduce or prevent the stray light from being emitted to the light receiving layer 16 through the insulating layer IN2. In some embodiments, the black matrix 26 may be disposed on the light blocking pattern 40 and be in contact with the light blocking pattern 40, but not limited thereto. For other parts of the electronic device 2a and other steps of the manufacturing method of the electronic device 2a in this modified embodiment may be identical or similar to the aforementioned embodiment, and therefore, will not be redundantly detailed.

Refer to FIG. 8. FIG. 8 schematically illustrates a top view of the electronic device according to some embodiments of the present disclosure. As shown in a part P4 of FIG. 8, the opening OP5 of some embodiments may include two sub-openings OP51, and the sub-openings OP51 may at least respectively be disposed between the light emitting layers 18 of the corresponding second light emitting elements LE2 and the light receiving layer 16 in the top view. Furthermore, as shown in an enlarged cross-sectional view taken along line A-A′ of FIG. 8, the connecting parts CP2 of the metal layer M1 may respectively be connected to the connecting parts CP1 of the metal layer M1 through the sub-openings OP51, and therefore, the connecting parts CP2 may reduce or prevent the stray light from being emitted to the light receiving layer 16 through the insulating layer IN1. In order to clearly show the opening OP5, the top view of FIG. 8 neglects the metal layer M2. In some embodiments, the metal layer M1 in the top view of FIG. 8 may be replaced with the metal layer M2. In some embodiments of FIG. 8, the metal layer M1 may include a mesh structure, but not limited thereto. In other embodiments, at least one of the metal layer M1 and the metal layer M2 may, for example, include the mesh structure.

In some embodiments, the light emitting layer 18 of the second light emitting element LE2 and the light receiving layer 16 may be arranged along the first direction D1, and in the second direction D2 perpendicular to the first direction D1, the width of the sub-opening OP51 may be greater than the width of the light receiving layer 16 and/or the width of the light emitting layer 18, but not limited thereto.

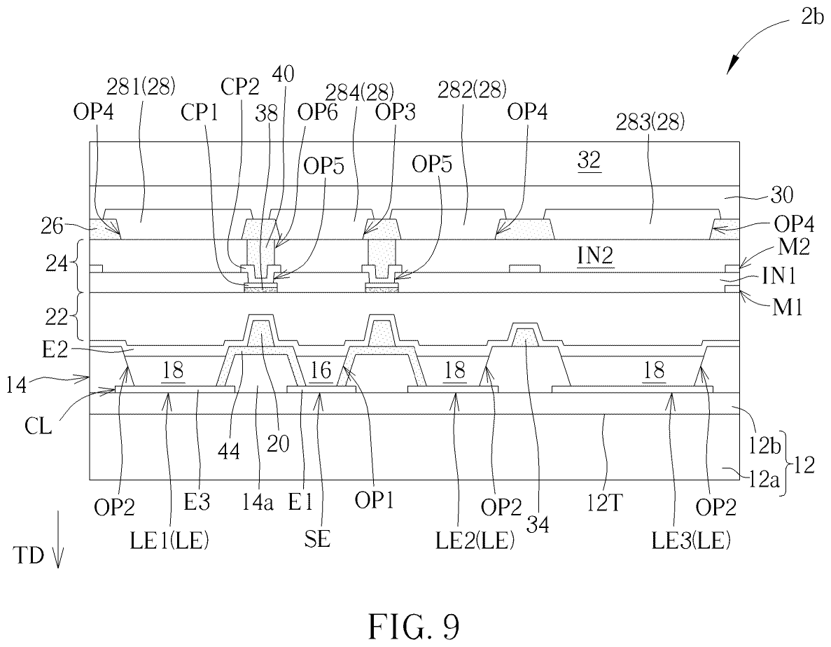

In a part P5 of FIG. 8, the opening OP5 of some embodiments may include a plurality of sub-openings OP51 arranged around the light receiving layer 16 in the top view of the electronic device, and the metal layer M2 may be connected to the metal layer M1 through the sub-openings OP51. In some embodiments, at least two of the adjacent sub-openings OP51 may be connected to each other, or the sub-openings OP51 may be connected to form the single opening OP5 surrounding the light receiving layer 16. The top view structure of the sub-opening OP51 in any one of the part P4 and the part P5 of FIG. 8 may, for example, be applied to any one of the aforementioned electronic devices in FIG. 3, FIG. 4, and FIG. 7 or any one of the following electronic devices in FIG. 9 and FIG. 11 to FIG. 14.

Refer to FIG. 9. FIG. 9 schematically illustrates a cross-sectional view of the electronic device according to a second modified embodiment of the second embodiment of the present disclosure. As shown in FIG. 9, a difference between the electronic device 2b of this modified embodiment and the electronic device 2 in FIG. 5 is that the partition layer 14 of this modified embodiment may include transparent insulating material, and the electronic device 2b may further include a light blocking pattern 44 at least disposed on the partition wall 14a adjacent to the light receiving layer 16 and used to reduce or prevent the stray light from being emitted to the light receiving layer 16. For example, the light blocking pattern 44 may cover the sidewall and the upper surface of the partition wall 14a. The light blocking pattern 44 may, for example, include black material or other suitable light blocking materials.

In the embodiment of FIG. 9, the sensing layer 24 may adopt the structure of the sensing layer 24 in FIG. 7, but not limited thereto. In some embodiments, the sensing layer 24 may adopt the structure of the sensing layer 24 in FIG. 5. In some embodiments, the electronic device 2b of FIG. 9 may selectively include the light blocking pattern 38 and/or the light blocking pattern 40 of FIG. 3, but not limited thereto. For other parts of the electronic device 2b and other steps of the manufacturing method of the electronic device 2b of this modified embodiment may be identical or similar to the aforementioned embodiment, and therefore, will not be redundantly detailed.

Refer to FIG. 10. FIG. 10 schematically illustrates a top view of the electronic device according to a third embodiment of the present disclosure. As shown in FIG. 10, a difference between the electronic device 3 of this embodiment and the electronic device of the aforementioned embodiment is that the light emitting elements LE may further include a fourth light emitting element LE4 disposed on one side of the light receiving layer 16 in the top view of the electronic device 3. For example, the fourth light emitting element LE4 may replace one of the second light emitting elements LE2 in FIG. 6 or FIG. 8, but not limited thereto. In the embodiment of FIG. 10, the fourth light emitting element LE4 may be used as the detection light source of the light sensing element SE but not be used to display the image, and therefore, the light emitting layer 18 of the fourth light emitting element LE4 emits light in the sense mode while emits no light in the display mode. Because the fourth light emitting element LE4 emits light in the sense mode, the opening OP5 may at least be disposed between the light emitting layer 18 of the fourth light emitting element LE4 and the light receiving layer 16, but not limited thereto. It is noted that since the fourth light emitting element LE4 may be independently used for detecting image, the first light emitting element LE1 to the third light emitting element LE3 may be independently used for displaying the image in the display mode. In other words, the first light emitting element LE1 to the third light emitting element LE3 are not used for detecting image, such that the lifespans of the first light emitting element LE1 to the third light emitting element LE3 may be increased. In some embodiments, as the electronic device 3 is operated in the sense mode, at least one of the first light emitting elements LE1 to the third light emitting element LE3 may emit light for detecting image.

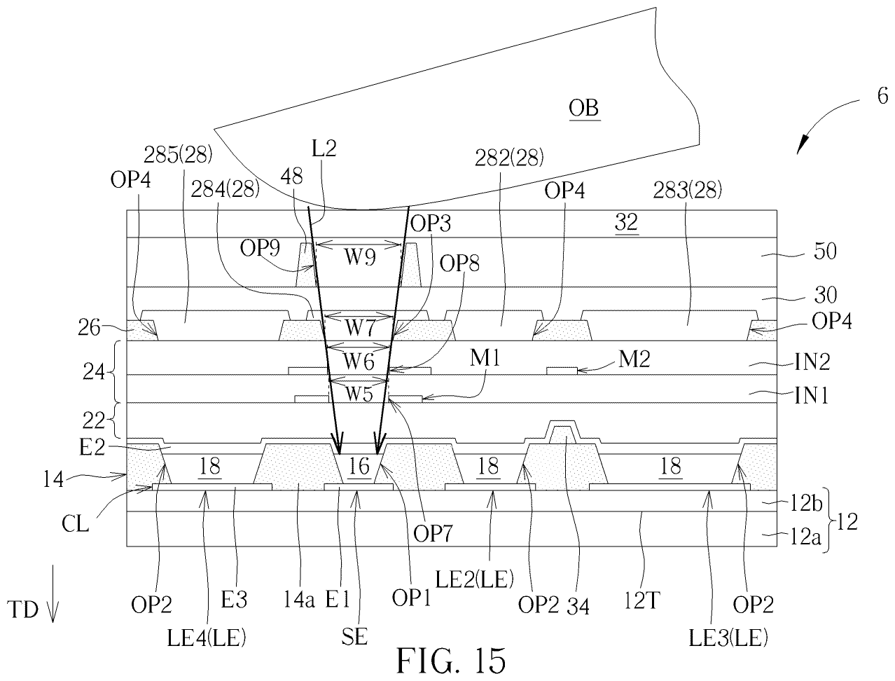

In some embodiments, the opening OP5 may at least partially surround the light receiving layer 16, or may include a plurality of the sub-openings OP51 arranged around the light receiving layer 16. In some embodiments, the fourth light emitting element LE4 may, for example, emit light with the same color as that of the second light emitting element LE2, but not limited thereto. In order to clearly show the opening OP5, the metal layer M2 is neglected in FIG. 10. In some embodiments, the metal layer M1 may be replaced with the metal layer M2. In some embodiments, the fourth light emitting element LE4 may emit light with the same color as that of the first light emitting element LE1 or the third light emitting element LE3. A cross-sectional structure of the fourth light emitting element LE4 and the corresponding color filter may, for example, be shown in one of FIG. 15 to FIG. 17, but not limited thereto. For other parts of the electronic device 3 and other steps of the manufacturing method of the electronic device 3 of this embodiment may be identical or similar to the aforementioned embodiment, and therefore, will not be redundantly detailed.

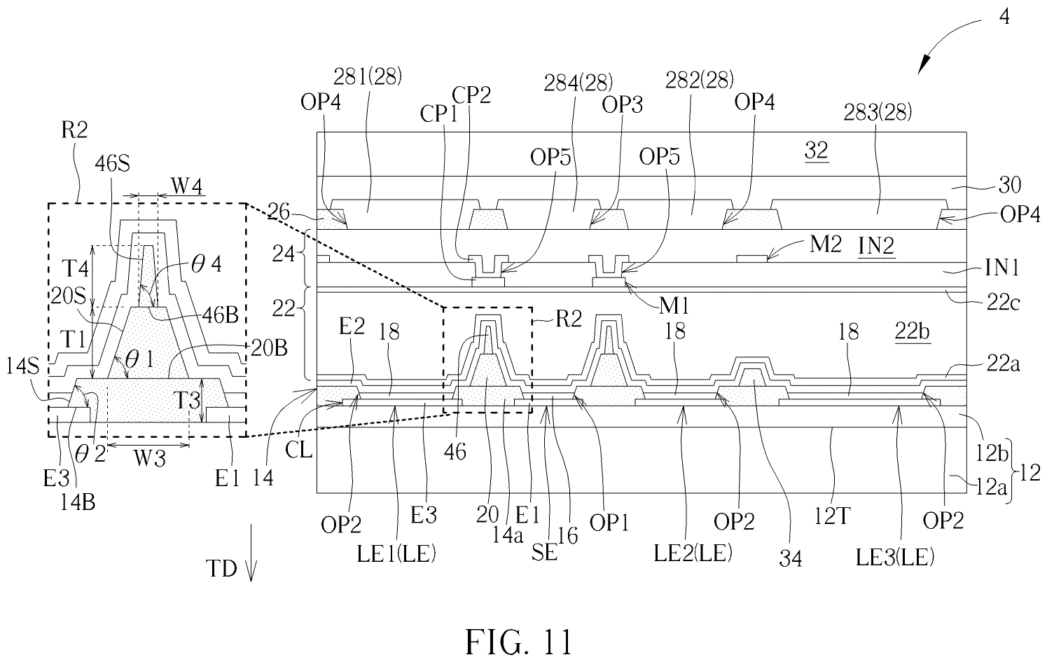

Refer to FIG. 11. FIG. 11 schematically illustrates a cross-sectional view of the electronic device according to a fourth embodiment of the present disclosure. As shown in FIG. 11, a difference between the electronic device 4 of this embodiment and the electronic device 2 of FIG. 5 is that the electronic device 4 may further include a light blocking pattern 46 disposed on the light blocking pattern 20. By the light blocking pattern 46, a thickness of a part of the encapsulation layer 22 on the light blocking pattern 20 may be reduced, thereby reducing or preventing the stray light from being emitted to the light receiving layer 16. In the embodiment of FIG. 11, the electrode E2 may be disposed on the light blocking pattern 46, but not limited thereto.

In FIG. 11, the insulating IN1 of the sensing layer 24 may include the opening OP5, wherein the connecting part CP2 of the metal layer M2 may penetrate through the opening OP5 and may be connected to the connecting part CP1 of the metal layer M1, and the opening OP5 may be overlapped with the light blocking pattern 20, but not limited thereto. In some embodiments, the electronic device 4 of FIG. 11 may adopt the sensing layer 24 shown in FIG. 5. Or, the electronic device 4 may further optionally include the light blocking pattern 38 and/or the light blocking pattern 40 shown in FIG. 3.

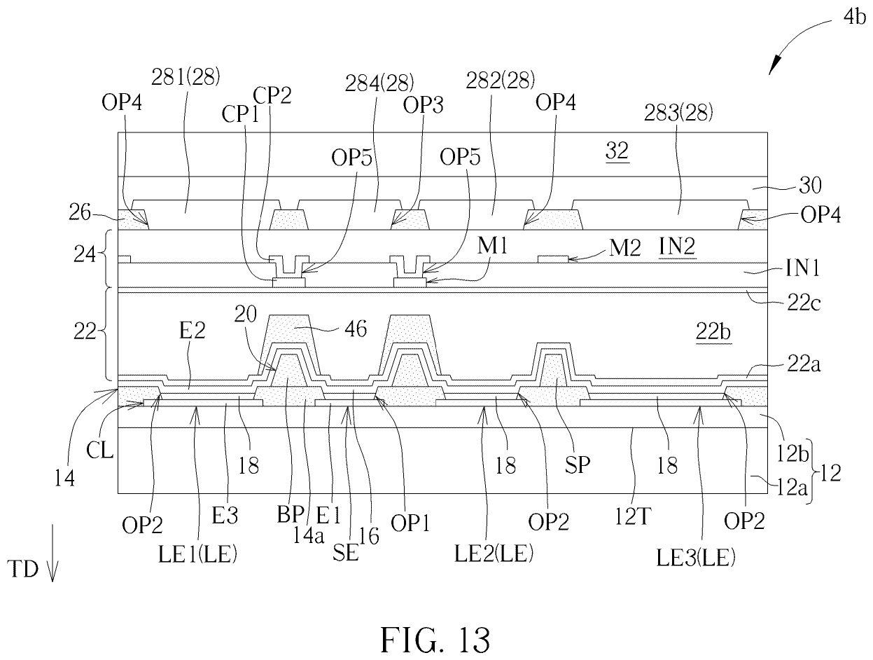

As shown in an enlarged view of a region R2 of FIG. 11, in the cross-sectional view of the electronic device 4, a width W3 of the bottom surface 20B of a part of the light blocking pattern 20 corresponding to the partition wall 14a may be greater than or equal to a width W4 of the bottom surface 46B of the part of the light blocking pattern 46 corresponding to the partition wall 14a. Under this circumstance, the thickness T1 of the light blocking pattern 20 may be greater than or equal to a thickness T4 of the light blocking pattern 46, but not limited thereto. In some embodiments, the thickness T3 of the partition wall 14a may be less than or equal to the thickness T1 of the light blocking pattern 20, but not limited thereto. In some embodiments, the angle θ2 between the sidewall 14S of the partition wall 14a and the bottom surface 14B of the partition wall 14a facing the conductor layer CL, the angle θ1 between the sidewall 20S of the light blocking pattern 20 and the bottom surface 20B of the light blocking pattern 20, and an angle θ4 between a side surface 46S of the light blocking pattern 46 and a bottom surface 46B of the light blocking pattern 46 may not be identical to each other, but not limited thereto. For example, the manufacturing condition and/or material of the light blocking pattern 20 and the light blocking pattern 46 may be identical to or different from each other. In some embodiments, the light blocking pattern 46 of FIG. 11 may be further disposed on the sidewall of the light blocking pattern 20 as shown in FIG. 13.

In the manufacturing method of the electronic device 4 of FIG. 11, after the light blocking pattern 20 and the spacer 34 are formed, the light emitting elements 18 and the light receiving layer 16 may be formed, and afterwards, the light blocking pattern 46 is formed on the light blocking pattern 20. Next, the electrode E2 and the encapsulation layer 22 are sequentially formed on the light blocking pattern 46. For other parts of the electronic device 4 and other steps of the manufacturing method of the electronic device 4 of this embodiment may be identical or similar to the aforementioned embodiment, and therefore, will not be redundantly detailed.

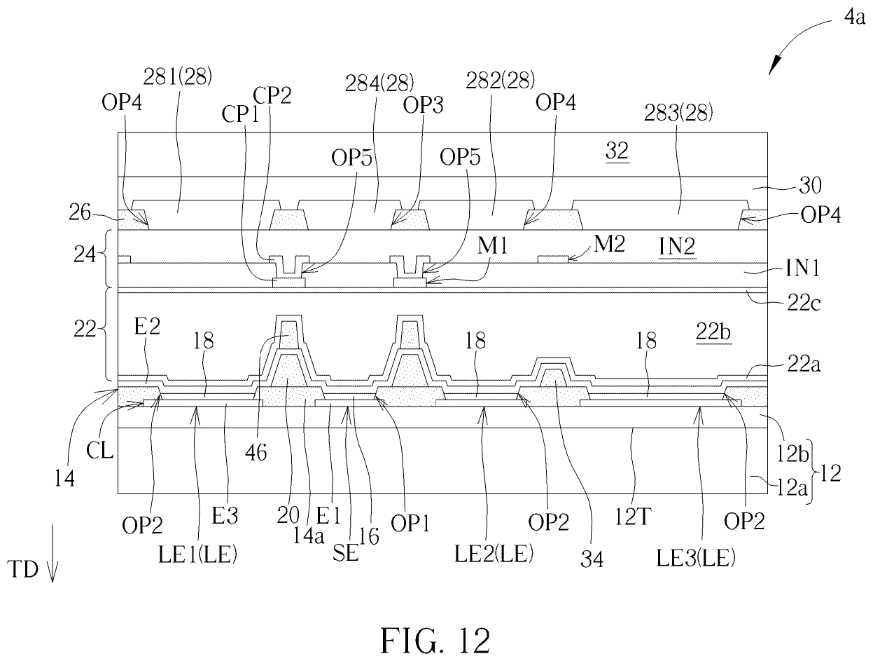

Refer to FIG. 12. FIG. 12 schematically illustrates a cross-sectional view of the electronic device according to a first modified embodiment of the fourth embodiment of the present disclosure. A difference between the electronic device 4a of this modified embodiment and the electronic device 4 of FIG. 11 is that the electrode E2 may be disposed between the light blocking pattern 20 and the light blocking pattern 46. In other words, the electrode E2 may be formed on the light blocking pattern 20, the light receiving layer 16, and the light emitting layer 18 before the light blocking pattern 46 is formed. Then, the light blocking pattern 46 may be formed on the electrode E2. In the embodiment of FIG. 12, the light blocking pattern 46 may be disposed between the electrode E2 and the encapsulation layer 22, but not limited thereto. In some embodiments, the light blocking pattern 46 may further be extended to the sidewall 20S of the light blocking pattern 20, for example, as shown in FIG. 13, but not limited thereto. In some embodiments, the light blocking pattern 46 of FIG. 12 may, for example, be disposed on the sidewall of the light blocking pattern 20 as shown in FIG. 13. For other parts of the electronic device 4a and other steps of the manufacturing method of the electronic device 4a of this modified embodiment may be identical or similar to the aforementioned embodiment, and therefore, will not be redundantly detailed.

Refer to FIG. 13. FIG. 13 schematically illustrates a cross-sectional view of the electronic device according to a second modified embodiment of the fourth embodiment of the present disclosure. A difference between the electronic device 4b of this modified embodiment and the electronic device 4a of FIG. 12 is that the light blocking pattern 46 may be disposed between the inorganic material layer 22a and the organic material layer 22b. In the embodiment of FIG. 13, the light blocking pattern 46 may further be extended to the sidewall 20S of the light blocking pattern 20. For example, in the top view of the electronic device 4b, the light blocking pattern 46 may cover a part of the light blocking pattern 20 corresponding to the partition wall 14a, or a width of the light blocking pattern 46 may be greater than the width of the part of the light blocking pattern 20 corresponding to the partition wall 14a, but not limited thereto. In some embodiments, the width of the light blocking pattern 46 of FIG. 13 may be less than the width of the light blocking pattern 20.

As shown in FIG. 13, the light blocking pattern 20 may include a light blocking part BP and a spacing part SP, wherein the light blocking part BP may be disposed on the partition wall 14a adjacent to the light receiving layer 16 to shield the stray light from entering the light receiving layer 16, and the spacing part SP may be disposed on a part of partition layer 14 between two adjacent openings OP2. Under this circumstance, the light blocking part BP and the spacing part SP may be used as spacers to support the mask, such that the circuit substrate 12b may be reduced or prevented from being damaged by collision with the mask. In the embodiment of FIG. 13, the light blocking part BP and the spacing part SP may, for example, have identical thickness. In the manufacturing method of the electronic device 4b of FIG. 13, after the inorganic material layer 22a of the encapsulation layer 22 is formed, the light blocking pattern 46 may be formed on the inorganic material layer 22a, and then, the organic material layer 22b and inorganic material layer 22c are sequentially formed on the light blocking pattern 46. For other parts of the electronic device 4b and other steps of the manufacturing method of the electronic device 4b of this modified embodiment may be identical or similar to the aforementioned embodiment, and therefore, will not be redundantly detailed.

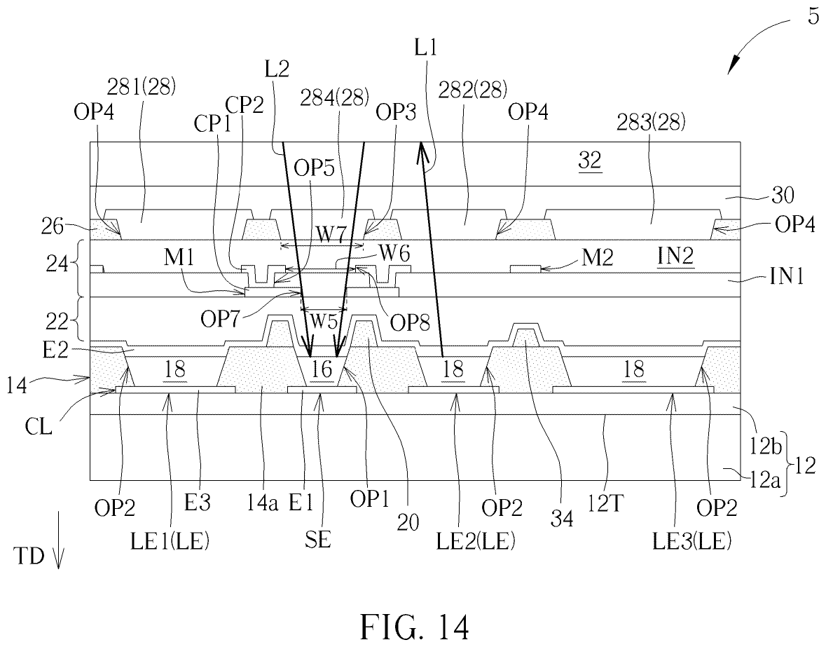

Refer to FIG. 14. FIG. 14 schematically illustrates a cross-sectional view of the electronic device according to a fifth embodiment of the present disclosure. As shown in FIG. 14, a difference between the electronic device 5 of this embodiment and the electronic device 2 of FIG. 5 is that the connecting part CP1 of the metal layer M1 may include an opening OP7 overlapped with the light receiving layer 16, the connecting part CP2 of the metal layer M2 may include an opening OP8 overlapped with the light receiving layer 16, and a width W5 of the opening OP7 may be less than a width W6 of the opening OP8, such that the light L2 reflected by the object to be detected (e.g., the object OB to be detected in FIG. 1) may be collimated by the opening OP8 and the opening OP7. In the embodiment of FIG. 14, the width W6 of the opening OP8 may be less than a width W7 of the opening OP3 of the black matrix 26. Because the opening OP3, the opening OP8, and the opening OP7 are in sequence from furthest to nearest according to the distance between itself and the light receiving layer 16, and the width W7 of the opening OP3, the width W6 of the opening OP8, and the width W5 of the opening OP7 gradually decrease in sequence, the light L2 may be further collimated to enhance the light signal received by the light receiving layer 16. In some embodiments, as viewed along the top view direction TD, a distance between two parts of the light blocking pattern 20 on two opposite sides of the light receiving layer 16 may be close to a maximum width of the opening OP1 of the partition layer 14, such that the light L2 may be further concentrated on the light receiving layer 16.

In the embodiment of FIG. 14, the width W5 of the opening OP7 may be less than a width W8 of the upper surface of the light receiving layer 16, such that enhancing the effect of concentrating light on the light receiving layer 16, but not limited thereto. Under this condition, the width W5 of the opening OP7 may be less than the distance between the parts of the light blocking pattern 20 on two opposite sides of the light receiving layer 16. In some embodiments, the width W5 of the opening OP7 may be greater than the width W8 of the upper surface of the light receiving layer 16.

In some embodiments, the insulating IN1 of the sensing layer 24 may include the opening OP5, wherein the connecting part CP2 of the metal layer M2 may penetrate through the opening OP5 and may be connected to the connecting part CP1 of the metal layer M1, and the opening OP5 may be overlapped with the light blocking pattern 20, but not limited thereto. In some embodiments, the sensing layer 24 may not include the opening OP5 overlapped with the light blocking pattern 20. In some embodiments, the electronic device 5 may optionally include the light blocking pattern 38 and/or the light blocking pattern 40 of FIG. 3, but not limited thereto. In some embodiments, the light blocking pattern 20 may, for example, be replaced with a metal pattern, and the metal pattern may include a through hole to guide light to the receiving layer 16. For other parts of the electronic device 5 and other steps of the manufacturing method of the electronic device 5 of this embodiment may be identical or similar to the aforementioned embodiment, and therefore, will not be redundantly detailed.

Refer to FIG. 15. FIG. 15 schematically illustrates a cross-sectional view of the electronic device according to a sixth embodiment of the present disclosure. As shown in FIG. 15, a difference between the electronic device 6 of this embodiment and the electronic device 2 of FIG. 5 is that the electronic device 6 may include a collimating pattern 48 disposed between the protective layer 30 and the covering layer 32, which provides the effect of collimating the light L2 reflected by the object OB to be detected. For example, the collimating pattern 48 in the top view may include at least two parts respectively disposed on two opposite sides of the light receiving layer 16, and each part of the collimating pattern 48 in the cross-sectional view may, for example, have a trapezoid cross-sectional shape, such that a width of an opening OP9 of the collimating pattern 48 may be shrunk as the distance between the light receiving layer 16 is reduced, but not limited thereto. In FIG. 15, the electronic device 6 may not include the light blocking pattern 20 in the above-mentioned contents, but not limited thereto.

In FIG. 15, the smallest width W9 of the opening OP9 may, for example, be greater than the width W7 of the opening OP3 of the black matrix 26, and the width W7 of the opening OP3, the width W6 of the opening OP8, and the width W5 of the opening OP7 may decrease in sequence in order to enhance the effect of collimating the light L2, but not limited thereto. The collimating pattern 48 may, for example, include colored organic and/or inorganic material, metal, transparent material with its surface coated with non-transparent material, or other suitable light blocking materials.

In the embodiment of FIG. 15, the electronic device 6 may further include an organic material layer 50 disposed on the collimating pattern 48 and the protective layer 30, and the organic material layer 50 may have an even upper surface used for disposing the covering layer 32. In the manufacturing method of the electronic device 6, after the protective layer 30 is formed, the collimating pattern 48 may be formed on the protective layer 30, and then, the organic material layer 50 and the covering layer 32 are sequentially formed on the collimating pattern 48 and the protective layer 30. The organic material layer 50 may, for example, include identical or similar material to the organic material layer of the encapsulation layer 22.

In FIG. 15, the light emitting elements LE may include the fourth light emitting element LE4, and the light emitting layer 18 of the fourth light emitting element LE4 may be next to the light receiving layer 16 of the light sensing element SE. In addition, the color filters 28 may include a fifth color filter 285 overlapped with the light emitting layer 18 of the fourth light emitting element LE4, but not limited thereto. A color of the fifth color filter 285 may correspond to the color of the light emitted by the fourth light emitting element LE4. For example, as the fourth light emitting element LE4 emits light with the same color as that of the second light emitting element LE2, the fifth color filter 285 may have the same color as that of the second color filter 282, but not limited thereto.

In the embodiment of FIG. 15, the insulating layer IN1 of the sensing layer 24 may adopt the structure of the insulating layer IN1 of FIG. 5 and may not have openings, but not limited thereto. In some embodiments, the sensing layer 24 may adopt the structure of the sensing layer 24 of FIG. 7, such that the metal layer M1 may be connected to the metal layer M2 through the opening OP5. In some embodiments, the electronic device 6 of FIG. 15 may optionally include the light blocking pattern 38 and/or the light blocking pattern 40 of FIG. 3, but not limited thereto. For other parts of the electronic device 6 and other steps of the manufacturing method of the electronic device 6 may be identical or similar to the aforementioned embodiment, and therefore, will not be redundantly detailed.

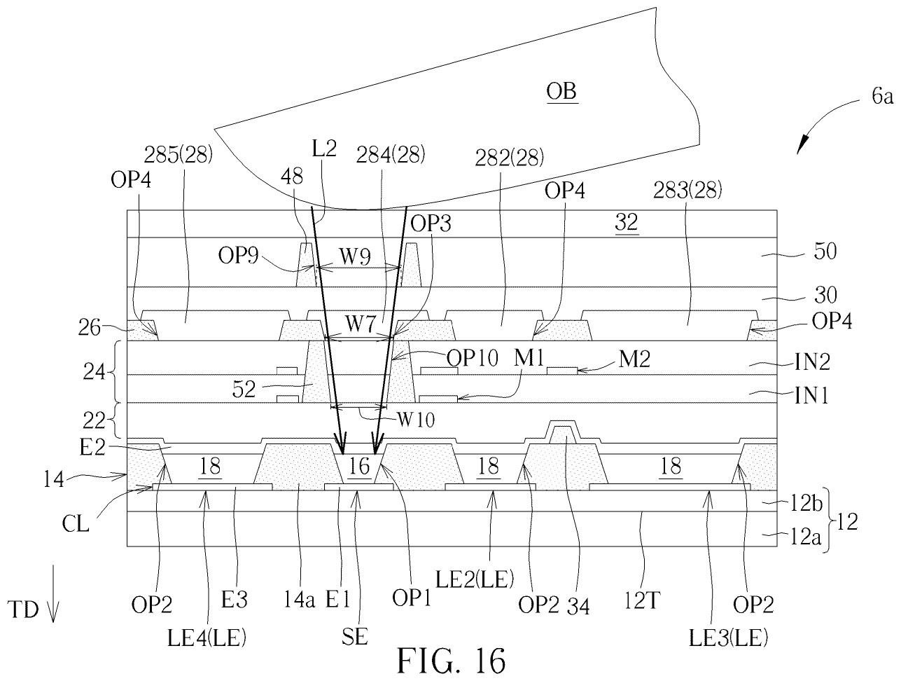

Refer to FIG. 16. FIG. 16 schematically illustrates a cross-sectional view of the electronic device according to a modified embodiment of the sixth embodiment of the present disclosure. As shown in FIG. 16, a difference between the electronic device 6a of this modified embodiment and the electronic device 6 of FIG. 15 is that the electronic device 6a may further include another collimating pattern 52 disposed between the encapsulation layer 22 and the collimating pattern 48. For example, the collimating pattern 52 may be disposed in the sensing layer 24, and the encapsulation layer 22 may not include through holes, such that the protection ability of the encapsulation layer 22 may be enhanced. A shape of the collimating pattern 52 may be similar or identical to the shape of the collimating pattern 48, and in other words, two parts of the collimating pattern 52 on two opposite sides of the light receiving layer 16 in the cross-sectional view may, for example, have the trapezoid cross-sectional shape. It is noted that a width of an opening OP10 of the collimating pattern 52 may be less than the width of the opening OP9 of the collimating pattern 48, such that the light L2 may be guided by the collimating pattern 52 and the collimating pattern 48 towards the light receiving layer 16 to increase the intensity of the light signal. For example, a smallest width W10 of the opening OP10 may be less than the smallest width W9 of the opening OP9. In the embodiment of FIG. 16, the metal layer M1 and the metal layer M2 of the sensing layer 24 are not disposed in the opening OP10 of the collimating pattern 52 to reduce or prevent light from being blocked by the metal layer M1 and the metal layer M2.

In the manufacturing method of the electronic device 6a of FIG. 16, the collimating pattern 52 may be formed in the step of forming the sensing layer 24, but not limited thereto. For other parts of the electronic device 6a and other steps of the manufacturing method of the electronic device 6a may be identical or similar to the aforementioned embodiment, and therefore, will not be redundantly detailed.

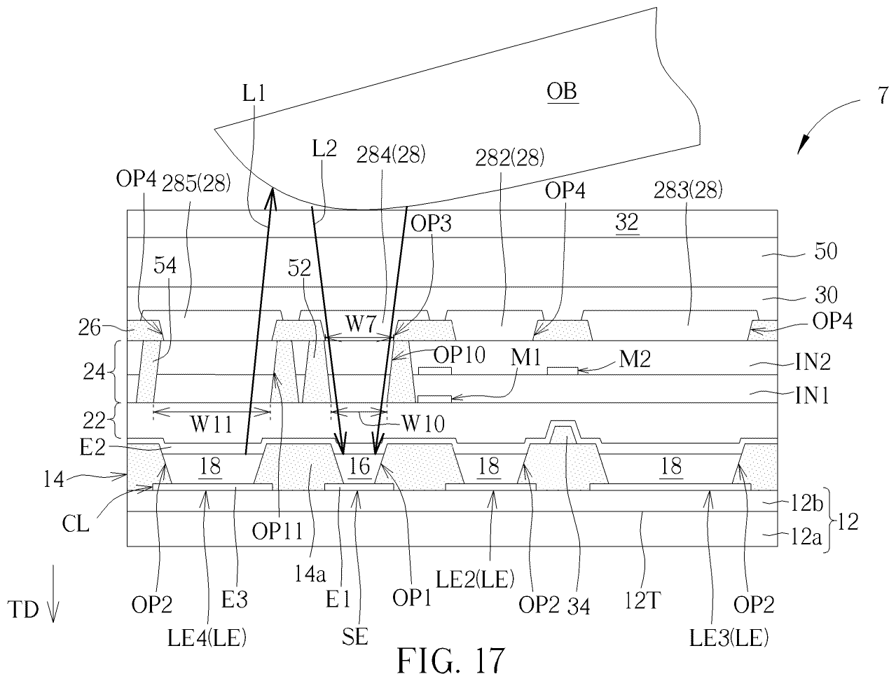

Refer to FIG. 17. FIG. 17 schematically illustrates a cross-sectional view of the electronic device according to a seventh embodiment of the present disclosure. As shown in FIG. 17, the electronic device 7 of this embodiment and the electronic device 6a of FIG. 16 is that the electronic device 7 may further include a guiding structure 54 disposed on the partition layer 14 and used to guide the light L1 emitted by the light emitting layer 18 of the fourth light emitting element LE4 toward the object OB to be detected. For example, the guiding structure 54 may, for example, include the same material or formed by the same process as the collimating pattern 52. Or, the guiding structure 54 may be formed during forming the sensing layer 24, but not limited thereto. The guiding structure 54 may, for example, include colored organic and/or inorganic material, metal, transparent material with its surface coated with non-transparent material, or other suitable light blocking materials.

In the embodiment of FIG. 17, the guiding structure 54 may include at least two parts respectively disposed on two opposite sides of the light emitting layer 18 of the fourth light emitting element LE4 in the top view of the electronic device 7, wherein an angle between the sidewall and the bottom surface of one of the parts of the guiding structure 54 may be greater than 90 degrees, such that the light L1 may be emitted out the electronic device 7 in a direction not parallel to the top view direction TD. For example, the parts of the guiding structure 54 away from the light receiving layer 16 may have a parallelogram cross-sectional shape while the part of the guiding structure 54 adjacent to the light receiving layer 16 may have the trapezoid cross-sectional shape, such that the light L1 may be emitted toward the side close to the light receiving layer 16 to enhance the intensity of the light L2 reflected by the object OB to be detected. In some embodiments, the guiding structure 54 may have an opening OP11, and the opening OP11 may, for example, have an even width W11, but not limited thereto.

In FIG. 17, there may be no collimating pattern disposed on the black matrix 26 of the electronic device 7, but not limited thereto. In some embodiments, the electronic device 7 may optionally include the collimating pattern 48 of FIG. 16. For other parts of the electronic device 7 and other steps of the manufacturing method of the electronic device 7 may be identical or similar to the aforementioned embodiment, and therefore, will not be redundantly detailed.

In summary, in the electronic device of the present disclosure, because the light blocking pattern may be disposed on the partition wall between the light receiving layer and the corresponding light emitting layer, the light emitted by the corresponding light emitting layer may be blocked by the light blocking pattern, which may reduce amount of the light emitted by the light emitting layer entering the light receiving layer without shining on the object to be detected. Accordingly, the SNR of the light signal received by the light receiving layer may be enhanced, and the accuracy of identifying the image may be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a circuit substrate;
a partition layer disposed on the circuit substrate, comprising a first opening, a second opening, and a partition wall disposed between the first opening and the second opening;
a light receiving layer disposed in the first opening;
a light emitting layer disposed in the second opening; and
a first light blocking pattern disposed on the partition wall;
wherein in a cross-sectional view of the electronic device, the first light blocking pattern has a first width at a first height and a second width at a second height higher than the first height, and the first width is different from the second width.

2. The electronic device according to claim 1, wherein the second width is greater than the first width.

3. The electronic device according to claim 2, further comprising an encapsulation layer disposed on the partition layer, wherein the first light blocking pattern is through the encapsulation layer.

4. The electronic device according to claim 3, further comprising a sensing layer disposed on the encapsulation layer, wherein the first light blocking pattern is through the sensing layer.

5. The electronic device according to claim 4, wherein the first light blocking pattern comprises a first sub-layer being through the encapsulation layer and a second sub-layer being through the sensing layer.

6. The electronic device according to claim 1, further comprising an electrode electrically connected to the light receiving layer and the light emitting layer, wherein the electrode is disposed between the partition wall and the first light blocking pattern.

7. The electronic device according to claim 1, wherein the second width is less than the first width.

8. The electronic device according to claim 7, further comprising an electrode electrically connected to the light receiving layer and the light emitting layer, wherein the electrode is disposed on the first light blocking pattern.

9. The electronic device according to claim 8, wherein the first light blocking pattern is in contact with the partition layer.

10. The electronic device according to claim 8, further comprising a second light blocking pattern disposed on the first light blocking pattern.

11. The electronic device according to claim 10, wherein the electrode is disposed on the second light blocking pattern.

12. The electronic device according to claim 10, wherein the electrode is disposed between the first light blocking pattern and the second light blocking pattern.

13. The electronic device according to claim 1, wherein a ratio of a thickness of the first light blocking pattern to a thickness of the partition layer is ranged from 1 to 10.

14. The electronic device according to claim 1, wherein in a top view of the electronic device, the first light blocking pattern surrounds the light receiving layer.

15. The electronic device according to claim 1, wherein the electronic device is capable of operating in a display mode or a sense mode, wherein the light emitting layer is configured to emit light in the sense mode and configured not to emit light in the display mode.

16. The electronic device according to claim 1, further comprising a sensing layer disposed on the partition layer, wherein the sensing layer comprises a first metal layer, a second metal layer, and an insulating layer disposed between the first metal layer and the second metal layer.

17. The electronic device according to claim 16, wherein the insulating layer comprises a third opening, the first metal layer is connected to the second metal layer through the third opening, and the third opening is overlapped with the first light blocking pattern.

18. The electronic device according to claim 17, wherein in a top view of the electronic device, the third opening comprises a plurality of sub-openings arranged around the light receiving layer.

19. The electronic device according to claim 17, further comprising a third light blocking pattern disposed on the second metal layer, wherein the third light blocking pattern is overlapped with the third opening.

20. The electronic device according to claim 17, further comprising a fourth light blocking pattern disposed under the first metal layer, wherein the fourth light blocking pattern is overlapped with the third opening.
